(19) United States
(12) Patent Application Publication
(10) Pub. No.: US 2023/0348317 A1
(43) Pub. Date: Nov. 2, 2023

(54) GLASS, AND METHOD FOR MEASURING DIELECTRIC PROPERTIES USING SAME

(71) Applicant: Nippon Electric Glass Co., Ltd., Shiga (JP)

(72) Inventor: Ryota SUZUKI, Shiga (JP)

(21) Appl. No.: 18/025,053

(22) PCT Filed: Sep. 2, 2021
(86) PCT No.: PCT/JP2021/032336

§ 371 Date: Mar. 7, 2023

(30) Foreign Application Priority Data
Sep. 8, 2020 (JP) 2020-150209
Dec. 2, 2020 (JP) 2020-200170
Apr. 9, 2021 (JP) 2021-066679

(51) Int. Cl. C03C 3/091; C03C 4/16

(52) U.S. Cl. CPC C03C 4/16; C03C 3/091

(57) ABSTRACT

A glass according to the present invention is characterized by having a rate of change of 30% or less in a dielectric loss tangent at a measurement temperature of 25° C. and a measurement frequency of 2.45 GHz after being subjected to a constant temperature/constant humidity test for 1000 hours at a temperature of 85° C. and a relative humidity of 85%.

### TECHNICAL FIELD

The present invention relates to a glass and a method for measuring dielectric properties using the same, and specifically relates to a glass used as a measurement standard material (dielectric constant standard material) when measuring dielectric properties at a frequency in a bandwidth used by fifth-generation mobile communication systems (5G), and a method for measuring dielectric properties using the glass.

### BACKGROUND ART

Developments to support fifth-generation mobile communication systems (5G) are currently under way, and technologies for increasing the speed and transmission capacities of such systems and reducing delays are being examined.

The frequencies to be used in fifth-generation mobile communication systems (5G) are assumed to be 3.7 GHz, 4.5 GHz, 28 GHz, 39 GHz, and the like. Ordinarily, the dielectric loss of an electrical signal propagating through a system increases at higher frequencies. However, the dielectric loss of an electrical signal can be reduced by lowering the relative dielectric constant and dielectric loss tangent of the surrounding constituent material through which the electrical signal propagates (see Non-Patent Document 1). Thus, reducing the dielectric properties of the constituent material is desired.

Incidentally, examples of methods for measuring dielectric properties include a cavity resonator method and an equilibrium disc resonator method (see Non-Patent Documents 2 and 3). In addition, Teflon and alumina, which are generally readily available, are used as measurement standard materials when measuring dielectric properties.

Non-Patent Documents 4 and 5 disclose plans for supplying dielectric constant standard materials to be used when measuring the dielectric properties of a constituent material in a high frequency range. In addition, Non-Patent Document 4 indicates that quartz glass and alkali-free glass are being used as candidates for measurement standard materials.

### CITATION LIST

### Non-Patent Documents

Non-Patent Document 1: Journal of The Japan Institute of Electronics Packaging, Vol. 22, No. 2 (2019), p. 172, Yuzo USUI
Non-Patent Document 2: Metal, Vol. 89, No. 2 (2019), p. 42 (144), Evaluation of Dielectric Properties and Radio Wave Absorption Characteristics, Daisuke IKIMI
Non-Patent Document 3: S.B. Research Co., Ltd., homepage, 1630560467110_0.htm, search date: Dec. 3, 2019
Non-Patent Document 4: Technical Information Institute Co., Ltd. Seminar Text, Low Dielectric Constant of High Frequency Compatible Substrate Materials, Reducing Dielectric Loss Tangent and Reducing Transmission Loss, seminar date: Oct. 22, 2018, Technology for Measuring Dielectric Constant of High-Frequency Substrate Materials and Application Thereof, Yuto KATO, Presentation Materials, p. 16
Non-Patent Document 5: Metrology Standard Development Plan (Physical Standard) 1630560467110_1.pdf, search date: Dec. 3, 2019

### DISCLOSURE OF THE INVENTION

### Technical Problem

As described above, Teflon and alumina are used as measurement standard materials, but these materials are hygroscopic. It is also known that dielectric properties in the high frequency range change with moisture. Therefore, the use of Teflon or alumina as a measurement standard material impairs the reliability of the dielectric property measurements.

It is also presumed that because quartz glass is expensive and the supply amount is small in comparison to other glasses, the use of quartz glass as a measurement standard material is difficult. Alkali-free glass generally does not have the low dielectric properties required in a fifth-generation mobile communication system (5G), and is thus unsuitable as a measurement standard material for dielectric properties.

Furthermore, glass having a low dielectric property generally contains a large amount of B₂O₃ in the composition, and therefore the moisture resistance tends to be low.

The present invention was achieved in view of the above circumstances, and the technical problem to be addressed by the present invention is to provide a glass having high moisture resistance while having low dielectric properties and a method for measuring dielectric properties using the glass.

### Solution to Problem

The present inventors repeatedly conducted various experiments, and as a result, discovered a glass in which the dielectric property does not easily change in tests such as a constant temperature/constant humidity test and a constant high-temperature/constant high-humidity test (unsaturated pressurized steam), and proposed the glass as the present invention. That is, the glass of the present invention is characterized in that the glass has a rate of change of 30% or less in a dielectric loss tangent at a measurement temperature of 25° C. and a measurement frequency of 2.45 GHz after the glass is subjected to a constant temperature/constant humidity test for 1000 hours at a temperature of 85° C. and a relative humidity of 85%. Here, the term “glass” used in the present invention includes not only amorphous glass, but also crystallized glass. Furthermore, the dielectric loss tangent at a measurement frequency of 2.45 GHz and a measurement temperature of 25° C. can be measured by, for example, a well-known cavity resonator method. Herein, the rate of change in the dielectric loss tangent refers to a value calculated by the equation [(dielectric loss tangent after test - dielectric loss tangent before test)/(dielectric loss tangent after test)] x 100.

Moreover, the glass of the present invention preferably has a rate of change of 30% or less in the dielectric loss tangent at a measurement temperature of 25° C. and a measurement frequency of 2.45 GHz after the glass is subjected to a constant high-temperature/constant high-humidity test (JIS-C 0096-2001) for 12 hours at a temperature of 120° C. and a relative humidity of 85%. Note that as the test apparatus for the constant high-temperature/constant high-humidity test, for example, the PC-242HSR2 unsaturated high-speed lifetime testing apparatus available from Hirayama Manufacturing Corporation can be used.

Additionally, it is preferable that, when the X-ray intensity of boron is analyzed in a depth direction from an outermost surface of the glass of the present invention, after the glass has been subjected to the constant high-temperature/constant high-humidity test (JIS-C0096-2001) for 48 hours at a temperature of 120° C. and a relative humidity of 85%, a depth at which an X-ray intensity of boron is reduced by 50% compared to an X-ray intensity of boron at a depth of 15 µm is 5 µm or less. Note that the “depth at which boron is reduced” is determined as follows: a cut surface of the glass is used as an analysis sample; when an element analysis is conducted in the depth direction from the outermost surface of the glass, the characteristic X-ray intensity value (unit: count) of a Kα line of the boron element is analyzed for spot analysis; and the measurement value of the analysis is used. Note that regarding the outermost surface, that is, a depth of 0 µm, when the cut surface is measured, the beam of the irradiated X-ray may not be properly sized to be irradiated onto the fractured surface. Thus, for the X-ray intensity of boron at a depth of 0 µm, the measurement value of the outermost surface of side of the glass is used. The X-ray intensity of boron can be analyzed using, for example, an electron probe micro analyzer (EPMA) (EPMA-1720, available from Shimadzu Corporation).

Also, the glass of the present invention is preferably such that in the composition, a product of the content (mol%) of B₂O₃ — Al₂O₃ and the content (mol%) of B₂O₃ — (MgO + CaO + SrO + BaO) is 260 or less. By configuring in this manner, moisture resistance can be significantly increased. Note that the content of “B₂O₃ — Al₂O₃” is obtained by subtracting the content of Al₂O₃ from the content of B₂O₃. The content of “B₂O₃ — (MgO + CaO + SrO + BaO)” is obtained by subtracting the total content of MgO, CaO, SrO, and BaO from the content of B₂O₃. Phase separation of the glass, or in other words, separation into a phase with a large amount of B₂O₃ and a phase with a small amount of B₂O₃, can be suppressed by increasing the content of Al₂O₃ compared to the content of B₂O₃ and increasing the content of the alkaline earths compared to the content of the B₂O₃. As a result, a decrease in B₂O₃ due to a weather resistance test can be suppressed.

Also, the glass of the present invention is preferably a crystallized glass. Through this, the moisture resistance can be enhanced.

Further, the glass of the present invention is preferably such that the composition of the glass includes from 60 to 75 mol% of SiO₂, from 0 to 15 mol% of Al₂O₃, from 8 to 28 mol% of B₂O₃, from 0 to 3 mol% of Li₂O + Na₂O + K₂O, and from 0 to 14 mol% of MgO + CaO + SrO + BaO, and the glass has the relative dielectric constant of 6 or less at 25° C. and a frequency of 2.45 GHz. In this manner, a glass having high moisture resistance while also having a low dielectric property can be obtained.

Moreover, the glass of the present invention is preferably such that the composition of the glass includes from 75 to 85 mol% of SiO₂, from 0 to 5 mol% of Al₂O₃, from 10 to 20 mol% of B₂O₃, from 0 to 5 mol% of Li₂O, from 1 to 10 mol% of Na₂O, from 0 to 5 mol% of K₂O, and from 3 to 10 mol% of Li₂O + Na₂O + K₂O, and the glass has the relative dielectric constant of 6 or less at 25° C. and a frequency of 2.45 GHz. In this manner, a glass having high moisture resistance while also having a low dielectric property can be obtained.

The glass of the present invention is also preferably such that the composition of the glass includes from 55 to 75 mol% of SiO₂, from 10 to 20 mol% of Al₂O₃, 2 mol% or greater of Li₂O, from 0.5 to 3 mol% of TiO₂, from 2 to 5 mol% of TiO₂ + ZrO₂, and from 0.1 to 0.5 mol% of SnO₂, and the glass has the relative dielectric constant of 7 or less at 25° C. and a frequency of 2.45 GHz. In this manner, a glass having high moisture resistance while also having a low dielectric property can be obtained.

Moreover, the glass of the present invention is preferably used as a measurement standard material in a measurement of dielectric properties.

A method for measuring dielectric properties according to the present invention is a method for measuring dielectric properties using a measurement standard material, and is characterized by using the glass described above as the measurement standard material. In this manner, dielectric properties can be stably measured for a long period of time

Additionally, the method for measuring dielectric properties according to the present invention preferably includes subjecting the measurement standard material to heat treatment at a temperature equal to or higher than the annealing point of the glass before measuring the dielectric properties. Through this, if the dielectric properties of the measurement standard material have changed, the dielectric properties of the measurement standard material can be restored to the initial values.

### BRIEF DESCRIPTION OF DRAWINGS

FIG. 1 is a graph showing the results of a composition analysis of boron in a glass cross-section of Sample Nos. 7 and 25 in the section of Example 3.

FIG. 2 is a graph showing the impact on the dielectric loss tangent with respect to a change in composition of the glass surface in Sample Nos. 7, 25, and 26 in the section of Example 3.

FIG. 3 shows reflectance spectra of Sample Nos. 7, 25 and 26 in the section of Example 3, (a) is the reflectance spectrum of Sample No. 7, (b) is the reflectance spectrum of Sample No. 25, and (c) is the reflectance spectrum of Sample No. 26.

FIG. 4 shows transmittance spectra of Sample Nos. 7, 25, and 26 in the section of Example 3, (a) is the transmittance spectrum of Sample No. 7, (b) is the transmittance spectrum of Sample No. 25, and (c) is the transmittance spectrum of Sample No. 26.

FIG. 5 is a graph showing a change in β—OH values of Sample Nos. 7, 25, and 26 in the section of Example 3.

FIG. 6 is graphs showing the relationship between the β—OH value and the dielectric loss tangent at a temperature of 25° C. and a frequency of 2.45 GHz for Sample Nos. 7, 25 and 26 in the section of Example 3, (a) shows the relationship between the β—OH value and the dielectric loss tangent at a temperature of 25° C. and a frequency of 2.45 GHz for Sample No. 7, (b) shows the relationship between the β—OH value and the dielectric loss tangent at a temperature of 25° C. and a frequency of 2.45 GHz for Sample No. 25, and (c) shows the relationship between the β—OH value and the dielectric loss tangent at a temperature of 25° C. and a frequency of 2.45 GHz for Sample No. 26.

### DESCRIPTION OF EMBODIMENTS

In a glass of the present invention, a rate of change in the dielectric loss tangent at a measurement temperature of 25° C. and a measurement frequency of 2.45 GHz after the glass has been subjected to a constant temperature/constant humidity test for 1000 hours at a temperature of 85° C. and a relative humidity of 85% is preferably 30% or less, 29% of less, 28% or less, 27% or less, 26% or less, 25% or less, 24% or less, 23% or less, 22% or less, 21% or less, 20% or less, 19% or less, 18% or less, 17% or less, 16% or less, 15% or less, 14% or less, 13% or less, 12% or less, 11% or less, 10% or less, 9% or less, 8% or less, 7% or less, 6% or less, 5% or less, 4% or less, 3% or less, or 2% or less, and is particularly preferably 1% or less. When the rate of change in the dielectric tangent is too high, the moisture resistance of the glass is easily reduced, and it becomes difficult to apply the glass in a high-frequency device or the like.

In the glass of the present invention, the rate of change in the dielectric loss tangent at a measurement temperature of 25° C. and a measurement frequency of 2.45 GHz after the glass has been subjected to a constant high-temperature/constant high-humidity test (JIS-C0096-2001) for 12 hours at a temperature of 120° C. and a relative humidity of 85% is preferably 30% or less, 29% of less, 28% or less, 27% or less, 26% or less, 25% or less, 24% or less, 23% or less, 22% or less, 21% or less, 20% or less, 19% or less, 18% or less, 17% or less, 16% or less, 15% or less, 14% or less, 13% or less, 12% or less, 11% or less, 10% or less, 9% or less, 8% or less, 7% or less, 6% or less, 5% or less, 4% or less, 3% or less, or 2% or less, and is particularly preferably 1% or less. When the rate of change in the dielectric loss tangent is too high, the moisture resistance of the glass is easily reduced, and it becomes difficult to apply the glass in a high-frequency device or the like.

In the glass of the present invention, the rate of change in the dielectric loss tangent at a measurement temperature of 25° C. and a measurement frequency of 2.45 GHz after the glass has been subjected to a constant high-temperature/constant high-humidity test (JIS-C0096-2001) for 48 hours at a temperature of 120° C. and a relative humidity of 85% is preferably 30% or less, 29% of less, 28% or less, 27% or less, 26% or less, 25% or less, 24% or less, 23% or less, 22% or less, 21% or less, 20% or less, 19% or less, 18% or less, 17% or less, 16% or less, 15% or less, 14% or less, 13% or less, 12% or less, 11% or less, 10% or less, 9% or less, 8% or less, 7% or less, 6% or less, 5% or less, 4% or less, 3% or less, or 2% or less, and is particularly preferably 1% or less. When the rate of change in the dielectric loss tangent is too high, the moisture resistance of the glass is easily reduced, and it becomes difficult to apply the glass in a high-frequency device or the like.

In the glass of the present invention, when an X-ray intensity of boron is analyzed in a depth direction from an outermost surface after the glass has been subjected to the constant high-temperature/constant high-humidity test (JIS-C0096-2001) for 48 hours at a temperature of 120° C. and a relative humidity of 85%, a depth at which the X-ray intensity of boron is reduced by 50% compared to the X-ray intensity of boron at a position at a depth of 15 µm is preferably 5.0 µm or less, 4.9 µm or less, 4.8 µm or less, 4.7 µm or less, 4.6 µm or less, 4.5 µm or less, 4.4 µm or less, 4.3 µm or less, 4.2 µm or less, 4.1 µm or less, 4.0 µm or less, 3.9 µm or less, 3.8 µm or less, 3.7 µm or less, 3.6 µm or less, 3.5 µm or less, 3.4 µm or less, 3.3 µm or less, 3.2 µm or less, 3.1 µm or less, 3.0 µm or less, 2.9 µm or less, 2.8 µm or less, 2.7 µm or less, 2.6 µm or less, 2.5 µm or less, 2.4 µm or less, 2.3 µm or less, 2.2 µm or less, 2.1 µm or less, 2.0 µm or less, 1.9 µm or less, 1.8 µm or less, 1.7 µm or less, 1.6 µm or less, 1.5 µm or less, 1.4 µm or less, 1.3 µm or less, 1.2 µm or less, 1.1 µm or less, 1.0 µm or less, 0.9 µm or less, 0.8 µm or less, 0.7 µm or less, 0.6 µm or less, 0.5 µm or less, 0.4 µm or less, 0.3 µm or less, 0.2 µm or less, 0.1 µm or less, or 0.0 µm or less. When the reduction depth of boron at this time is too large, the moisture resistance of the glass is easily reduced, and it becomes difficult to apply the glass in a high-frequency device or the like.

In the glass of the present invention, when the constant high-temperature/constant high-humidity test (JIS-C0096-2001) is conducted for 48 hours at a temperature of 120° C. and a relative humidity of 85% and then the glass is maintained for 3 hours at a temperature of the annealing point of the glass plus 30° C. and then cooled to room temperature at a rate of -3° C./minute, after which the X-ray intensity of boron is analyzed in the depth direction from the outermost surface, the depth at which the X-ray intensity of boron is reduced by 50% compared to the X-ray intensity of boron at a position at a depth of 15 µm is preferably 10.0 µm or less, 9.0 µm or less, 8.0 µm or less, 7.0 µm or less, 6.0 µm or less, 5.0 µm or less, 4.9 µm or less, 4.8 µm or less, 4.7 µm or less, 4.6 µm or less, 4.5 µm or less, 4.4 µm or less, 4.3 µm or less, 4.2 µm or less, 4.1 µm or less, 4.0 µm or less, 3.9 µm or less, 3.8 µm or less, 3.7 µm or less, 3.6 µm or less, 3.5 µm or less, 3.4 µm or less, 3.3 µm or less, 3.2 µm or less, 3.1 µm or less, 3.0 µm or less, 2.9 µm or less, 2.8 µm or less, 2.7 µm or less, 2.6 µm or less, 2.5 µm or less, 2.4 µm or less, 2.3 µm or less, 2.2 µm or less, 2.1 µm or less, 2.0 µm or less, 1.9 µm or less, 1.8 µm or less, 1.7 µm or less, 1.6 µm or less, 1.5 µm or less, 1.4 µm or less, 1.3 µm or less, 1.2 µm or less, 1.1 µm or less, 1.0 µm or less, 0.9 µm or less, 0.8 µm or less, 0.7 µm or less, 0.6 µm or less, 0.5 µm or less, 0.4 µm or less, 0.3 µm or less, 0.2 µm or less, 0.1 µm or less, or 0.0 µm or less. When the reduction depth of boron at this time is too large, the moisture resistance of the glass is easily reduced, and it becomes difficult to apply the glass in a high-frequency device or the like.

The glass of the present invention can have a variety of compositions, but of the various compositions, the glass preferably has a composition (glasses A to C) described below. The glass (glass A) of the present invention preferably contains, as a composition, from 60 to 75 mol% of SiO₂, from 0 to 15 mol% of Al₂O₃, from 8 to 28 mol% of B₂O₃, from 0 to 3 mol% of Li₂O + Na₂O + K₂O, and from 0 to 14 mol% of MgO + CaO + SrO + BaO. The reason for limiting the content of each component as described above is as follows. Note that “%” in the description below represents “mol%” unless otherwise indicated.

The content of SiO₂ is preferably from 60 to 75%, from 61 to 74%, from 62 to 72%, from 63 to 71%, from 64 to 70%, from 64 to 69.5%, or from 64 to 69%, and is particularly preferably from 65 to 67%. If the content of SiO₂ is too low, the relative dielectric constant, dielectric loss tangent, and density tend to increase. Moisture resistance also tends to decrease. On the other hand, if the content of SiO₂ is too high, the high-temperature viscosity becomes high, meltability decreases, and devitrified crystals such as cristobalite tend to precipitate during forming.

Al₂O₃ is a component that increases the Young’s modulus, and suppresses phase separation. Furthermore, Al₂O₃ is also a component that remarkably increases moisture resistance. Thus, the lower limit range of the content of Al₂O₃ is preferably 0% or greater, 0.1% or greater, 0.2% or greater, 0.3% or greater, 0.4% or greater, 0.5% or greater, 1% or greater, 2% or greater, 3% or greater, 4% or greater, or 5% or greater, and is particularly preferably 6% or greater. If the content of Al₂O₃ is too high, the liquid phase temperature becomes high, and devitrification resistance tends to decrease. The relative dielectric constant and dielectric loss tangent also tend to increase. Thus, the upper limit range of the Al₂O₃ is preferably 15% or less, 13% or less, 12% or less, 11% or less, 10.9% or less, 10.8% or less, 10.7% or less, 10.6% or less, 10.5% or less, 10% or less, 9.9% or less, 9.8% or less, 9.7% or less, 9.6% or less, 9.5% or less, 9.4% or less, 9.3% or less, 9.2% or less, 9.1% or less, 9.0% or less, 8.9% or less, 8.7% or less, 8.5% or less, 8.3% or less, 8.1% or less, 8% or less, 7.9% or less, 7.8% or less, 7.7% or less, 7.6% or less, 7.5% or less, 7.3% or less, or 7.1% or less, and is particularly preferably 7.0% or less.

B₂O₃ is a component that reduces the relative dielectric constant and dielectric loss tangent, but is also a component that reduces the Young’s modulus and density. B₂O₃ is a component that also reduces moisture resistance. However, when the content of B₂O₃ is too low, it becomes difficult to ensure low dielectric properties, and in addition, the action of B₂O₃ as a flux becomes insufficient, high-temperature viscosity increases, and the foam quality tends to be reduced. Reducing the density also becomes difficult. Thus, the lower limit range of B₂O₃ is preferably 8% or greater, 9% or greater, 10% or greater, 15% or greater, 18% or greater, 18.1% or greater, 18.2% or greater, 18.3% or greater, 18.4% or greater, 18.5% or greater, 19% or greater, 19.4% or greater, 19.5% or greater, 19.6% or greater, 20% or greater, or higher than 20%, and is particularly preferably 22% or greater. When the content of B₂O₃ is too high, heat resistance and chemical durability tend to decrease, and due to phase separation, moisture resistance also tends to decrease. Thus, the upper limit range of the content of B₂O₃ is preferably 28% or less, 27% or less, 26% or less, 25% or less, or 24% or less, and is particularly preferably 23% or less.

The content of B₂O₃ — Al₂O₃ is preferably -5% or greater, -4% or greater, -3% or greater, -2% or greater, -1% or greater, 0% or greater, 1% or greater, 2% or greater, 3% or greater, 4% or greater, 5% or greater, 6% or greater, 7% or greater, 8% or greater, or 9% or greater, and is particularly preferably 10% or greater. If the content of B₂O₃ — Al₂O₃ is too low, it becomes difficult to ensure a low dielectric property.

An alkali metal oxide is a component that enhances meltability and formability. However, when the content thereof is too high, the density increases, the moisture resistance decreases, the thermal expansion coefficient becomes unreasonably high, thermal shock resistance decreases, and it becomes difficult to match the thermal expansion coefficients of surrounding materials. Thus, the content of Li₂O + Na₂O + K₂O (the combined content of Li₂O, Na₂O and K₂O) is preferably from 0 to 3%, from 0 to 2%, from 0 to 1%, from 0 to 0.5%, from 0 to 0.2%, or from 0 to 0.1%, and is particularly preferably from 0.001 to less than 0.05%. The content of each of Li₂O, Na₂O and K₂O is preferably from 0 to 3%, from 0 to 2%, from 0 to 1%, from 0 to 0.5%, from 0 to 0.2%, or from 0 to 0.1%, and is particularly preferably from 0.001 to less than 0.01%.

An alkaline earth metal oxide is a component that lowers the liquid phase temperature and makes it difficult to generate a devitrified crystal in the glass, and is a component that enhances meltability and formability. The content of MgO + CaO + SrO + BaO (the combined content of MgO, CaO, SrO, and BaO) is preferably from 0 to 14%, from 0 to 12%, from 0 to 10%, from 0 to 8%, from 0 to 7%, from 1 to 7%, from 2 to 7%, or from 3 to 9%, and is particularly preferably from 3 to 6%. When the content of MgO + CaO + SrO + BaO is too low, the devitrification resistance tends to decrease, and in addition, the action as a flux cannot be sufficiently exhibited, and meltability tends to decrease. On the other hand, if the content of MgO + CaO + SrO + BaO is too high, the density increases, and it becomes difficult to achieve a weight reduction in the glass. In addition, the thermal expansion coefficient becomes unreasonably high, and thermal shock resistance tends to decrease.

MgO is a component that lowers the high temperature viscosity and enhances meltability without lowering the strain point, and is a component that is the least likely to increase in density among alkaline earth metal oxides. In addition, among alkaline earth metals, MgO is a component that particularly enhances moisture resistance. The content of MgO is preferably from 0 to 12%, from 0 to 10%, from 0.01 to 8%, from 0.1 to 6%, from 0.2 to 5%, from 0.3 to 4%, or from 0.5 to 3%, and is particularly preferably from 0.8 to 2%. However, when the content of MgO is too large, the liquid phase temperature increases, and the devitrification resistance tends to decrease. In addition, the glass undergoes phase separation and tends to decrease in transparency.

CaO is a component that decreases high-temperature viscosity and significantly increases meltability without lowering the strain point, and is a component that has a large effect of increasing devitrification resistance in the composition system of the glass A. In addition, among alkaline earth metals, CaO is a component that enhances moisture resistance. Thus, the lower limit range of CaO is preferably 0% or greater, 0.05% or greater, 0.1% or greater, 1% or greater, 1.1% or greater, 1.2% or greater, 1.3% or greater, 1.4% % or greater, or 1.5% or greater, and is particularly preferably 2% or greater. On the other hand, if the content of CaO is too large, the thermal expansion coefficient and density are unreasonably increased, the compositional balance of components is impaired, and devitrification resistance tends to decrease. Thus, the upper limit range of CaO is preferably 12% or less, 10% or less, 8% or less, 7% or less, 6% or less, 5% or less, 4.6% or less, 4.5% or less, 4.4% or less, or 4% or less, and is particularly preferably 3% or less.

SrO is a component that reduces high temperature viscosity and increases meltability without reducing the strain point, but when the content of SrO is too high, the liquid phase viscosity tends to decrease. Thus, the content of SrO is preferably from 0 to 10%, from 0 to 8%, from 0 to 7%, from 0 to 6%, from 0 to 5.1 %, from 0 to 5%, from 0 to 4.9%, from 0 to 4%, from 0 to 3%, from 0 to 2%, from 0 to 1.5%, from 0 to 1%, or from 0 to 0.5%, and is particularly preferably from 0 to 0.1%.

BaO is a component that reduces high temperature viscosity and increases meltability without reducing the strain point, but when the content of BaO is too high, the liquid phase viscosity tends to decrease. Thus, the content of BaO is preferably from 0 to 10%, from 0 to 8%, from 0 to 7%, from 0 to 6%, from 0 to 5%, from 0 to 4%, from 0 to 3%, from 0 to 2%, from 0 to 1.5%, from 0 to 1%, or from 0 to 0.5%, and is particularly preferably from 0 to less than 0.1%.

When the molar ratio of (MgO + CaO + SrO + BaO)/(SiO₂ + Al₂O₃ + B₂O₃) is too large, the moisture resistance tends to decrease. In addition, when a through-hole is to be formed by etching, the etching speed tends to increase, and the shape of the through-hole tends to become distorted (irregular). Furthermore, even when the through-hole is formed by laser irradiation, the accuracy of the hole opening tends to decrease. On the other hand, when the molar ratio of (MgO + CaO + SrO + BaO)/(SiO₂ + Al₂O₃ + B₂O₃) is too small, the high temperature viscosity increases, and the melting temperature increases, and thus the cost to manufacture a glass sheet tends to increase sharply. Therefore, the molar ratio of (MgO + CaO + SrO + BaO)/(SiO₂ + Al₂O₃ + B₂O₃) is preferably from 0.001 to 0.4, from 0.005 to 0.35, from 0.010 to 0.30, from 0.020 to 0.25, from 0.030 to 0.20, from 0.035 to 0.15, from 0.040 to 0.14, or from 0.045 to 0.13, and is particularly preferably from 0.050 to 0.10. Note that the “molar ratio of (MgO + CaO + SrO + BaO)/(SiO₂ + Al₂O₃ + B₂O₃)” indicates a value obtained by dividing the content of MgO + CaO + SrO + BaO by the content of SiO₂ + Al₂O₃ + B₂O₃.

If the molar ratio of (MgO + CaO + SrO + BaO)/Al₂O₃ is too small, the devitrification resistance decreases, and forming into a sheet shape by an overflow downdraw method tends to be difficult. On the other hand, when the molar ratio of (MgO + CaO + SrO + BaO)/Al₂O₃ is too large, the density and thermal expansion coefficient may unreasonably increase. Thus, the molar ratio of (MgO + CaO + SrO + BaO)/Al₂O₃ is preferably from 0.1 to 2.0, 0.1 to 1.5, 0.1 to 1.2, 0.2 to 1.2, 0.3 to 1.2, or 0.4 to 1.1, and is particularly preferably from 0.5 to 1.0. Note that the molar ratio of “(MgO + CaO + SrO + BaO)/Al₂O₃″ indicates a value obtained by dividing the content of MgO + CaO + SrO + BaO by the content of Al₂O₃.

The molar ratio of (SrO + BaO)/B₂O₃ is preferably 1.0 or less, 0.5 or less, 0.2 or less, 0.1 or less, 0.05 or less, or 0.03 or less, and is particularly preferably 0.02 or less. When the molar ratio of (SrO + BaO)/B₂O₃ is too large, it becomes difficult to ensure low dielectric properties, and it becomes difficult to increase the liquid phase viscosity. Note that “SrO + BaO” is the combined amount of SrO and BaO. Also, “(SrO + BaO)/B₂O₃″ indicates a value obtained by dividing the content of SrO + BaO by the content of B₂O₃.

B₂O₃ — (MgO + CaO + SrO + BaO) is preferably -5% or greater, 0% or greater, 5% or greater, 6% or greater, 7% or greater, 8% or greater, 9% or greater, 10% or greater, or 11% or greater, and is particularly preferably 12% or greater. When the content of B₂O₃ — (MgO + CaO + SrO + BaO) is too small, it becomes difficult to ensure low dielectric properties, the density tends to increase, and the Young’s modulus tends to decrease.

The molar ratio of (SrO + BaO)/(MgO + CaO) is preferably 400 or less, 300 or less, 100 or less, 50 or less, 10 or less, 5 or less, 2 or less, 1 or less, 0.8 or less, or 0.5 or less, and is particularly preferably 0.3 or less. When the molar ratio (SrO + BaO)/(MgO + CaO) is too large, it becomes difficult to ensure low dielectric properties, and the density tends to increase.

A product of the content (mol%) of B₂O₃ — Al₂O₃ and the content (mol%) of B₂O₃ — (MgO + CaO + SrO + BaO) is preferably 600 or less, 550 or less, 500 or less, 450 or less, 400 or less, 350 or less, 340 or less, 330 or less, 320 or less, 310 or less, 300 or less, 290 or less, 280 or less, or 270 or less, and is particularly preferably 260 or less. When the product of the content of B₂O₃ — Al₂O₃ and the content of B₂O₃ — (MgO + CaO + SrO + BaO) is too large, it becomes difficult to ensure moisture resistance, and the Young’s modulus tends to decrease. Also, the product of the content of B₂O₃ - Al₂O₃ and the content of B₂O₃ — (MgO + CaO + SrO + BaO) is preferably 1 or greater, 5 or greater, 10 or greater, 20 or greater, 30 or greater, 40 or greater, 50 or greater, 60 or greater, 70 or greater, 80 or greater, or 90 or greater, and is particularly preferably 100 or greater. When the product of the content of B₂O₃ — Al₂O₃ and the content of B₂O₃ — (MgO + CaO + SrO + BaO) is too small, it becomes difficult to ensure low dielectric properties, and the thermal expansion coefficient tends to be reduced.

In addition to the above components, a component described below may be introduced into the composition.

ZnO is a component that enhances meltability. However, when the composition contains a large amount of ZnO, the glass tends to devitrify, and the density tends to increase. Thus, the content of ZnO is preferably from 0 to 5%, from 0 to 3%, from 0 to 0.5%, or from 0 to 0.3%, and is particularly preferably from 0 to 0.1%.

ZrO₂ is a component that increases the Young’s modulus. The content of ZrO₂ is preferably from 0 to 5%, from 0 to 3%, from 0 to 0.5%, from 0 to 0.2%, from 0 to 0.16%, or from 0 to 0.1%, and is particularly preferably from 0 to 0.02%. When the content of ZrO₂ is too high, the liquid phase temperature increases, and devitrified crystals of zircon are easily precipitated.

TiO₂ is a component that lowers the high temperature viscosity and increases meltability, and is also a component that suppresses solarization. However, when the composition contains a large amount of TiO₂, the glass becomes colored, and the transmittance tends to decrease. Thus, the content of TiO₂ is preferably from 0 to 5%, from 0 to 3%, from 0 to 1%, or from 0 to 0.1%, and is particularly preferably from 0 to 0.02%.

P₂O₅ is a component that increases devitrification resistance. However, when the composition contains a large amount of P₂O₅, the glass phase separates and tends to become milky white, and the moisture resistance could be significantly reduced. Thus, the content of P₂O₅ is preferably from 0 to 5%, from 0 to 1%, or from 0 to 0.5%, and is particularly preferably from 0 to 0.1%.

SnO₂ is a component that has an excellent clarifying action in a high temperature range, and is a component that reduces high temperature viscosity. The content of SnO₂ is preferably from 0 to 1%, from 0.01 to 0.5%, or from 0.05 to 0.3%, and is particularly preferably from 0.07 to 0.2%. When the content of SnO₂ is too high, devitrified crystals of SnO₂ are likely to precipitate.

Fe₂O₃ is a component that may be introduced as an impurity component or a fining agent component. However, when the content of Fe₂O₃ is too large, ultraviolet transmittance may decrease. Thus, the content of Fe₂O₃ is preferably 0.05% or less or 0.03% or less, and is particularly preferably 0.02% or less. Here, the “Fe₂O₃”referred to in the present invention includes divalent iron oxide and trivalent iron oxide, and divalent iron oxide is converted to Fe₂O₃ and handled. Note that other polyvalent oxides are similarly handled on the basis of the indicated oxide.

SnO₂ is preferably added as the fining agent, but as long as the glass properties are not impaired, CeO₂, SO₃, C, and metal powders (such as, for example, Al and Si) may be added up to a content of 1%.

As₂O₃, Sb₂O₃, F, and Cl also effectively act as fining agents, and while the present invention does not exclude the content of these components, from an environmental perspective, the content of each of these components is preferably less than 0.1%,and is particularly preferably less than 0.05%.

The glass (glass B) of the present invention is preferably such that the composition of the glass includes from 75 to 85 mol% of SiO₂, from 0 to 5 mol% of Al₂O₃, from 10 to 20 mol% of B₂O₃, from 0 to 5 mol% of Li₂O, from 1 to 10 mol% of Na₂O, from 0 to 5 mol% of K₂O, and from 3 to 10 mol% of Li₂O + Na₂O + K₂O. The reason for limiting the content of each component as described above is as follows. Note that “%” in the description below represents “mol%” unless otherwise indicated.

SiO₂ is a main component forming a glass skeleton network. The content of SiO₂ is preferably from 75 to 85%, from 77 to 84%, from 78 to 83%, or from 77 to 82%, and is particularly preferably from 77 to 81%. When the content of SiO₂ is too low, the relative dielectric constant, dielectric loss tangent, and density tend to be high. Moisture resistance also tends to decrease. On the other hand, when the content of SiO₂ is too high, the high-temperature viscosity becomes high, meltability decreases, and devitrified crystals such as cristobalite tend to precipitate during forming.

Al₂O₃ is a component that increases chemical durability, mechanical strength, and devitrification resistance. The content of Al₂O₃ is preferably from 0 to 5%, from 1 to 4%, or from 1.1 to 3%, and is particularly preferably from 2 to 3%. When the content of Al₂O₃ is too high, high temperature viscosity increases, and meltability and formability tend to decrease.

B₂O₃ is a component that forms a glass skeletal structure and decreases the high temperature viscosity. The content of B₂O₃ is preferably from 10 to 20%, from 10 to 18%, or from 11 to 15%, and is particularly preferably from 12 to 15%. When the content of B₂O₃ is too high, the glass is prone to phase separation, and once phase separation has occurred, the thermal expansion coefficient and dielectric properties become non-uniform, and chemical durability tends to decrease. In addition, the amount of component evaporation from the molten glass increases, a heterogeneous layer is more easily formed on the surface of the molten glass, and the homogeneity of the glass tends to decrease. On the other hand, when the content of B₂O₃ is too small, the viscosity of the glass becomes too high. Maintaining low dielectric properties also becomes difficult.

Alkali metal oxides are components that decrease the viscosity of the glass and increase the meltability, but at the same time, alkali metal oxides are also components that increase the thermal expansion coefficient and dielectric properties. The content of Li₂O + Na₂O + K₂O is preferably from 3% to 10% or from 3.5% to 8%, and is particularly preferably from 4 to 5%. When the content of Li₂O + Na₂O + K₂O is too small, the viscosity of the glass increases, and the meltability tends to decrease. On the other hand, when the content of Li₂O + Na₂O + K₂O is too large, the thermal expansion coefficient and the dielectric properties increase, and the thermal shock resistance tends to decrease.

Li₂O is a component that reduces the viscosity at high temperatures and increases meltability. The content of Li₂O is preferably from 0 to 5% or from 0 to 3%, and is particularly preferably from 0 to 1%. When the content of Li₂O is too large, the thermal expansion coefficient becomes too high, and the thermal shock resistance tends to decrease. The dielectric properties also become too high.

Na₂O is a component that reduces the viscosity at high temperatures and increases meltability. The content of Na₂O is preferably from 1 to 10%, from 2 to 7%, or from 3 to 6.5%, and is particularly preferably from 4 to 6%. When the content of Na₂O is too low, high temperature viscosity increases, and meltability tends to decrease. On the other hand, when the content of Na₂O is too high, the thermal expansion coefficient and dielectric properties tend to become too high.

K₂O is a component that lowers the viscosity at high temperatures and increases meltability. The content of K₂O is preferably from 0 to 5% or from 0 to 3%, and is particularly preferably from 0 to 1%. When the content of K₂O is too high, the thermal expansion coefficient becomes too high, and the thermal shock resistance tends to decrease. The dielectric properties also become too high.

Other components may be introduced in addition to the above components. For example, in order to improve the thermal expansion coefficient, dielectric properties, high temperature viscosity, and the like, components such as MgO, CaO, SrO, BaO, ZnO, TiO₂, ZrO₂, SnO₂, P₂O₅, Cr₂O₃, Sb₂O₃, SO₂, Cl₂, PbO, La₂O₃, WO₃, Co₃O₄, Nb₂O₅, Y₂O₃, and CeO₂ may be contained. Note that the content of these components is preferably 3% or less as a combined amount.

Further, as trace components, H₂, CO₂, CO, He, Ne, Ar, N₂, and the like may be contained at a combined amount of up to 0.1%. In addition, the glass may contain precious metal elements such as Pt and Rh at a combined amount of up to 500 ppm as long as the dielectric properties are not adversely affected.

The glass (glass C) of the present invention is crystallized glass, and the composition of the glass preferably contains from 55 to 75 mol% of SiO₂, from 10 to 20 mol% of Al₂O₃, 2 mol% or move of Li₂O, from 0.5 to 3 mol% of TiO₂, from 2 to 5 mol% of TiO₂ + ZrO₂, and from 0.1 to 0.5 mol% of SnO₂. The reason for limiting the content of each component as described above is as follows. Note that “%” in the description below represents “mol%” unless otherwise indicated.

SiO₂ is a component that forms the skeleton of glass and is a constituent component of Li₂O—Al₂O₃—SiO₂ based crystals. SiO₂ is also a component that reduces dielectric properties. The content of SiO₂ is preferably from 55% to 75%, from 58% to 74%, or from 60% to 74%, and is particularly preferably from 65% to 73%. When the content of SiO₂ is too low, the thermal expansion coefficient tends to increase, and it becomes difficult to obtain a glass containing a crystal having excellent thermal shock resistance. In addition, chemical durability and moisture resistance tend to decrease. On the other hand, when the content of SiO₂ is too high, meltability decreases, the viscosity of the glass becomes high, clarifying becomes difficult, and forming of the glass tends to become difficult.

Al₂O₃ is a component that forms the skeleton of the glass and is a constituent component of Li₂O—Al₂O₃—SiO₂ based crystals. Further, when Al₂O₃ is present in the residual glass phase in the crystallized glass, the intensity of coloration of TiO₂ and Fe₂O₃ due to SnO₂ can be reduced. The content of Al₂O₃ is preferably from 10 to 20% or from 11 to 18%, and is particularly preferably from 12 to 17%. When the content of the Al₂O₃ is too low, the thermal expansion coefficient tends to increase, and it becomes difficult to obtain a glass having excellent thermal shock resistance. In addition, chemical durability and moisture resistance tend to decrease. Further, it becomes difficult to exert the effect of reducing the intensity of coloration of TiO₂ and Fe₂O₃ due to SnO₂. On the other hand, when the content of Al₂O₃ is too high, the meltability decreases, and the viscosity of the glass becomes high, and as a result, the glass is not easily fined, and the glass becomes difficult to form. In addition, mullite crystals are precipitated, devitrification of the glass tends to occur, and the glass is easily damaged.

Li₂O is a component constituting Li₂O—Al₂O₃—SiO₂ based crystals and has a large impact on crystallinity, and is also a component that reduces the glass viscosity and increases the meltability and formability. The content of the Li₂O is preferably 2% or greater, 2.5% or greater, 3% or greater, 4% or greater, or 5% or greater, and is particularly preferably 6% or greater. When the content of the Li₂O is too small, mullite crystals tend to precipitate, and devitrification of the glass tends to occur. Also, when the glass is crystallized, precipitation of Li₂O—Al₂O₃—SiO₂ based crystals does not easily occur, and it becomes difficult to obtain a glass with excellent thermal shock resistance. Furthermore, as a result of the decrease in the meltability and the increase in the viscosity of the glass, the glass is not easily fined, and the glass becomes difficult to form. On the other hand, when the content of the Li₂O is too high, the crystallinity becomes too strong, devitrification of the glass tends to occur, and the glass is easily damaged. Moisture resistance also decreases. Thus, the content of the Li₂O is preferably 10% or less or 9.5% or less, and is particularly preferably 9% or less.

TiO₂ is a component serving as a nucleating agent to precipitate crystals. The content of the TiO₂ is preferably from 0.5 to 3%, from 0.8 to 2.3%, from 1 to 2%, from 1.1 to 1.9%, from 1.2 to 1.8%, from 1.3 to 1.7%, or from 1.5 to 1.7%, and is particularly preferably from 1.6 to 1.7%. When the content of the TiO₂ is too high, coloration tends to be strong. In addition, devitrification of the glass tends to occur, and the glass is easily damaged. When the content of the TiO₂ is too low, crystal nuclei are not sufficiently formed, and coarse crystals may precipitate, causing white turbidity and/or breakage.

In addition to the components described above, a component described below can also be introduced.

MgO is a component that dissolves in Li₂O—Al₂O₃—SiO₂ based crystals to form a solid solution, and has an effect of increasing the thermal expansion coefficient of the Li₂O—Al₂O₃—SiO₂ based crystals. The content of MgO is preferably from 0% to 2%, from 0.1% to 1.5%, or from 0.3% to 1.3%, and is particularly preferably from 0.5% to 1.2%. When the content of MgO is too high, the crystallinity becomes too strong, and the glass is easily damaged.

Similar to MgO, ZnO is a component that dissolves in Li₂O—Al₂O₃— SiO₂ based crystals to form a solid solution. The content of ZnO is preferably from 0% to 2% or from 0% to 1.5%, and is particularly preferably from 0.1% to 1.2%. When the content of ZnO is too high, the glass may exhibit excessively pronounced crystallinity, and when the material is formed while being slowly cooled, devitrification of the glass tends to occur. As a result, the glass becomes more prone to damage, and therefore forming by the float method, for example, becomes difficult.

Note that the content of each component of SrO and CaO is not particularly limited as long as the content satisfies the above range, but for example, the content of SrO is preferably limited to 0.5% or less, and particularly preferably to 0.3% or less, and the content of CaO is preferably limited to 0.2% or less, and particularly preferably to 0.1% or less.

SnO₂ is a component that acts as a fining agent. The content of SnO₂ is preferably from 0.1 to 0.5%, or from 0.1 to 0.4%, and is particularly preferably from 0.1 to 0.3%. When the content of the SnO₂ is less than 0.1%, it becomes difficult to exert the effect as a fining agent. On the other hand, when the content of the SnO₂ is too high, the coloration of TiO₂ or Fe₂O₃ becomes too strong, which makes the glass more susceptible to yellowing. Devitrification also easily occurs.

Fe₂O₃ is a component that is mixed in as an impurity component. The content of Fe₂O₃ is preferably 300 ppm or less or 250 ppm or less, and is particularly preferably 200 ppm or less. A lower content of Fe₂O₃ results in lower coloration and thus is preferable. However, when the content amount of Fe₂O₃ is set to a range below 60 ppm for example, use of a high-purity raw material or the like becomes necessary, and as a result, the manufacturing cost of the glass tends to increase sharply.

Similar to TiO₂, ZrO₂ is a nucleating component for causing precipitation of crystals in a crystallization step. The content of ZrO₂ is preferably from 0 to 3% or from 0.1 to 2.5%, and is particularly preferably from 0.5 to 2.3%. When the content of ZrO₂ is too high, devitrification tends to occur when the glass is melted, and thus molding of the glass becomes difficult.

The content of TiO₂ + ZrO₂ (the combined content of TiO₂ and ZrO₂) is preferably from 2% to 5% or from 2.2% to 4.5%, and is particularly preferably from 2.3 to 3.8%. When the content of TiO₂ + ZrO₂ is within the range described above, a glass having the desired color tone and high transparency can be obtained.

B₂O₃ is a component that promotes the dissolution of the SiO₂ raw material in a melting step. The content of B₂O₃ is preferably from 0 to 2%, and is particularly preferably from 0 to less than 1%. When the content of B₂O₃ is too high, heat resistance tends to be impaired. The moisture resistance also decreases.

P₂O₅ is a component that promotes phase separation and assists in the formation of crystal nuclei. The content of P₂O₅ is preferably from 0 to 3% or from 0.1% to 2%, and is particularly preferably from 0.2% to 1%. When the content of the P₂O₅ is too high, the glass tends to undergo phase separation in the melting step, making it difficult to yield a glass having a desired composition. In addition, the glass tends to become opaque.

Also, in order to reduce the viscosity of the glass and increase meltability and moldability, Na₂O, K₂O, and BaO can be added at a combined content from 0 to 2%, and particularly from 0.1 to 2%. When the combined content of these components is too high, devitrification of the glass tends to easily occur.

The glass of the present invention preferably has the following characteristics.

The relative dielectric constant at 25° C. and a frequency of 10 GHz is preferably 7.0 or less, 6.9 or less, 6.8 or less, 6.7 or less, 6.6 or less, 6.5 or less, 6.4 or less, 6.3 or less, 6.2 or less, 6.1 or less, 6.0 or less, 5.9 or less, 5.8 or less, 5.7 or less, 5.6 or less, 5.5 or less, 5.4 or less, 5.3 or less, 5.2 or less, 5.1 or less, 5.0 or less, 4.9 or less, 4.8 or less, 4.7 or less, or 4.6 or less, and is particularly preferably 4.5 or less. When the relative dielectric constant is too high, the transmission loss when an electrical signal is transmitted to a high-frequency device is likely to be large.

The dielectric loss tangent at 25° C. and a frequency of 10 GHz is preferably 0.01 or less, 0.009 or less, 0.008 or less, 0.007 or less, 0.006 or less, 0.005 or less, or 0.004 or less, and is particularly preferably 0.003 or less. When the dielectric loss tangent is too high, the transmission loss when an electrical signal is transmitted to a high-frequency device is likely to be large.

The relative dielectric constant at 25° C. and a frequency of 2.45 GHz is preferably 7.0 or less, 6.9 or less, 6.8 or less, 6.7 or less, 6.6 or less, 6.5 or less, 6.4 or less, 6.3 or less, 6.2 or less, 6.1 or less, 6.0 or less, 5.9 or less, 5.8 or less, 5.7 or less, 5.6 or less, 5.5 or less, 5.4 or less, 5.3 or less, 5.2 or less, 5.1 or less, 5.0 or less, 4.9 or less, 4.8 or less, 4.7 or less, or 4.6 or less, and is particularly preferably 4.5 or less. When the relative dielectric constant is too high, the transmission loss when an electrical signal is transmitted to a high-frequency device is likely to be large.

The dielectric loss tangent at 25° C. and a frequency of 2.45 GHz is preferably 0.01 or less, 0.009 or less, 0.008 or less, 0.007 or less, 0.006 or less, 0.005 or less, or 0.004 or less, and is particularly preferably 0.003 or less. When the dielectric loss tangent is too high, the transmission loss when an electrical signal is transmitted to a high-frequency device is likely to be large.

The thermal expansion coefficient in a temperature range from 30 to 380° C. is preferably from 0×10⁻⁷ to 60×⁻⁷/°C, from 10×10⁻⁷ to 55×10⁻⁷/°C, from 20×10⁻⁷ to 50×10⁻⁷/°C, from 22×10⁻⁷ to 48×10⁻⁷/°C, from 23×10⁻⁷ to 47×10⁻⁷/°C, from 25×10⁻⁷ to 46×10⁻⁷/°C, from 28×10⁻⁷ to 45×10⁻⁷/°C, from 30×10⁻⁷ to 43×10⁻⁷/°C, or from 32×10⁻⁷ to 41×10⁻⁷/°C, and is particularly preferably from 35×10⁻⁷ to 39×10⁻⁷/°C. When the thermal expansion coefficient in the temperature range from 30 to 380° C. is outside of the range described above, the thermal expansion coefficient is not easily matched with the various peripheral members.

The Young’s modulus is preferably 40 GPa or higher, 41 GPa or higher, 43 GPa or higher, 45 GPa or higher, 47 GPa or higher, 50 GPa or higher, 51 GPa or higher, 52 GPa or higher, 53 GPa or higher, or 54 GPa or higher, and is particularly preferably 55 GPa or higher. When the Young’s modulus is too low, the glass tends to bend, and thus wiring defects are likely to occur during the production of a high-frequency device.

The refractive index nd (measurement wavelength 587.6 nm) is preferably 1.55 or less, 1.54 or less, 1.53 or less, 1.52 or less, 1.51 or less, 1.50 or less, 1.495 or less, 1.490 or less, 1.488 or less, 1.487 or less, 1.486 or less, 1.485 or less, 1.484 or less, 1.483 or less, 1.482 or less, 1.481 or less, or 1.480 or less, and is particularly preferably 1.479 or less. When the refractive index is too high, reflectance at the interface between air and the glass increases, and thus the intensity of light transmitted to the glass back surface becomes low, and wiring defects are likely to occur during production of the high-frequency device. Here, the “refractive index” is a value measured by a commercially available refractive index meter, and can be measured using, for example, the KPR-2000 available from Shimadzu Corporation.

The strain point is preferably 530° C. or higher, 540° C. or higher, 550° C. or higher, 560° C. or higher, 570° C. or higher, or 580° C. or higher, and is particularly preferably 590° C. or higher. When the strain point is too low, in a case where solidification through heating of an organic resin layer coated to protect the wiring is necessary in the production of the high-frequency device, the glass tends to undergo heat shrinkage. Therefore, wiring defects are likely to occur during production of the high-frequency device.

The liquid phase viscosity is preferably 10^{3.4} dPa•s or higher, 10^{3.6} dPa•s or higher, 10^{3.8} dPa•s or higher, 10^{4.0} dPa•s or higher, 10^{4.2} dPa•s or higher, 10^{4.6} dPa•s or higher, 10^{4.8} dPa•s or higher, or 10^{5.0} dPa•s or higher, and is particularly preferably 10^{5.2} dPa•s or higher. When the liquid phase viscosity is too low, devitrification of the glass tends to occur during molding.

The β—OH value is preferably 1.1 mm⁻¹ or lower, 0.6 mm⁻¹ or lower, 0.55 mm⁻¹ or lower, 0.5 mm⁻¹ or lower, 0.45 mm⁻¹ or lower, 0.4 mm⁻¹ or lower, 0.35 mm⁻¹ or lower, 0.3 mm⁻¹ or lower, 0.25 mm⁻¹ or lower, 0.2 mm⁻¹ or lower, 0.15 mm⁻¹ or lower, and is particularly preferably 0.1 mm⁻¹ or lower. When the β—OH value is too large, it becomes difficult to ensure low dielectric properties. Note that the “β —OH value” is a value calculated by the following mathematical equation using a commercially available Fourier transform infrared spectrophotometer (FT-IR).

$$β \text{-OH value =} \left(1 / \text{X}\right) log \left({\text{T}}_{1} / {\text{T}}_{2}\right)$$

X: sheet thickness (mm)
T₁: transmittance (%) at a reference wavelength of 3846 cm⁻¹
T₂: minimum transmittance (%) near a hydroxyl group absorption wavelength of 3600 cm⁻¹

The heat shrinkage rate when the temperature is increased at a rate of 5° C./min, held at 500° C. for 1 hour, and then decreased at a rate of 5° C./minute is preferably 30 ppm or less, 25 ppm or less, or 20 ppm or less, and is particularly preferably 18 ppm or less. When this heat shrinkage rate is too large, in a case where solidification through heating of an organic resin layer coated to protect the wiring is necessary in the production of the high-frequency device, the glass tends to undergo heat shrinkage. Therefore, wiring defects are likely to occur during production of the high-frequency device.

The thickness (sheet thickness in the case of a sheet shape) of the glass of the present invention is preferably 10 mm or less, 9 mm or less, 8 mm or less, 7 mm or less, 6 mm or less, 5 mm or less, 4 mm or less, 3 mm or less, 2 mm or less, 1 mm or less, 0.9 mm or less, 0.8 mm or less, 0.7 mm or less, 0.6 mm or less, 0.5 mm or less, or 0.4 mm or less, and is particularly preferably 0.3 mm or less. When the glass is too thick, it becomes difficult to reduce the weight and size of the high-frequency device.

The arithmetic mean roughness Ra of the surface is preferably 100 nm or less, 50 nm or less, 20 nm or less, 10 nm or less, 5 nm or less, 2 nm or less, or 1 nm or less, and is particularly preferably 0.5 nm or less. When the surface quality of the glass is smoother, the arithmetic average roughness Ra of the metal wiring formed on the glass surface decreases, and thus the resistance loss generated when current flows through the metal wiring of the high-frequency device can be reduced. In addition, the glass is less likely to break. On the other hand, the arithmetic mean roughness Ra of the surface is preferably 0.1 nm or greater or 0.2 nm or greater, and is particularly preferably 0.5 nm or greater. As the arithmetic mean roughness Ra of the surface becomes rougher, the metal wiring and functional film formed on the glass surface are less likely to separate off from the surface. Note that the “arithmetic mean roughness Ra” can be measured using a stylus-type surface roughness meter or an atomic force microscope (AFM).

The glass of the present invention is preferably formed by an overflow downdraw method. In this way, an unpolished glass sheet having good surface quality can be efficiently obtained. Various forming methods can be employed in addition to the overflow downdraw method. For example, a forming method such as a slot-down method, a float method, and a roll-out method can be employed.

A method for measuring dielectric properties according to the present invention is a method for measuring dielectric properties using a measurement standard material, and is characterized by using the glass described above as the measurement standard material. When a glass of the present invention is used as a measurement standard, the dielectric properties can be stably measured for a long period of time.

In the method for measuring dielectric properties according to the present invention, the frequency of the dielectric property to be measured is preferably 1 GHz or greater, 2 GHz or greater, 3 GHz or greater, 4 GHz or greater, 5 GHz or greater, 6 GHz or greater, 7 GHz or greater, 8 GHz or greater, or 9 GHz or greater, and is particular preferably 10 GHz or greater, and is also preferably 200 GHz or less, 150 GHz or less, or 120 GHz or less, and is particularly preferably 100 GHz or less. When the measurement frequency is outside the range described above, it becomes difficult to evaluate the dielectric properties of the constituent materials of a high-frequency device used in 5G communications or the like.

In the method for measuring dielectric properties according to the present invention, the measurement temperature is preferably from -40 to 150° C., from -30 to 130° C., from -20 to 120° C., from -10 to 110° C., from 0 to 100° C., from 10 to 90° C., or from 20 to 80° C., and is particularly preferably from 25 to 70° C. When the measurement temperature is outside the range described above, it becomes difficult to evaluate the dielectric properties of the constituent materials of a high-frequency device used in 5G communications or the like.

In the method for measuring dielectric properties according to the present invention, the glass that is to be used as the measurement standard material is preferably heated before the dielectric properties are measured. The heating temperature is preferably a temperature of greater than or equal to the annealing point of the glass, a temperature of greater than or equal to the annealing point plus 1° C., a temperature of greater than or equal to the annealing point plus 2° C., a temperature of greater than or equal to the annealing point plus 3° C., a temperature of greater than or equal to the annealing point plus 5° C., a temperature of greater than or equal to the annealing point plus 10° C., a temperature of greater than or equal to the annealing point plus 15° C., a temperature of greater than or equal to the annealing point plus 20° C., or a temperature of greater than or equal to the annealing point plus 25° C., and is particularly preferably a temperature of greater than or equal to the annealing point plus 29° C. When the heating temperature is high, the moisture in the glass decreases, but when the heating temperature is too high, the glass may soften and deform. Thus, the heating temperature is preferably a temperature of not greater than the softening point, a temperature of not greater than the softening point minus 100° C., a temperature of not greater than the softening point minus 200° C., a temperature of not greater than the softening point minus 250° C., a temperature of not greater than the softening point minus 280° C., a temperature of not greater than the softening point minus 300° C., a temperature of not greater than the softening point minus 320° C., a temperature of not greater than the softening point minus 330° C., or a temperature of not greater than the softening point minus 340° C., and is particularly preferably a temperature of not greater than the softening point minus 350° C. The heating time is preferably 10 minutes or longer, 20 minutes or longer, 30 minutes or longer, 40 minutes or longer, 50 minutes or longer, 60 minutes or longer, 70 minutes or longer, 80 minutes or longer, 90 minutes or longer, 100 minutes or longer, 110 minutes or longer, 120 minutes or longer, 130 minutes or longer, 140 minutes or longer, 150 minutes or longer, 160 minutes or longer, or 170 minutes or longer, and is particularly preferably 180 minutes or longer. When the heating time is long, the moisture in the glass decreases, but when the heating time is too long, the measurement efficiency deteriorates. Thus, the heating time is preferably 1000 minutes or less, 900 minutes or less, 800 minutes or less, 700 minutes or less, 600 minutes or less, 500 minutes or less, or 400 minutes or less, and is particularly preferably 300 minutes or less.

### Example 1

The present invention will be described in detail below based on examples. Note that the following examples are merely illustrative. The present invention is not limited in any way by the following examples.

Examples (Sample Nos. 1 to 16, 21, 26, 27, 28) of the present invention and comparative examples (Sample Nos. 17 to 20 and 22 to 25) are shown in Tables 1 to 6.

TABLE 1

| [mol%] | No. 1 | No. 2 | No. 3 | No. 4 | No. 5 | No. 6 | No. 7 | No. 8 | No. 9 |
|---|---|---|---|---|---|---|---|---|---|
| SiO₂ | 65.89 | 67.21 | 66.33 | 70.34 | 66.72 | 70.26 | 66.52 | 66.12 | 74.11 |
| Al₂O₃ | 4.39 | 5.08 | 6.56 | 7.98 | 8.51 | 6.08 | 10.69 | 4.67 | 3.99 |
| B₂O₃ | 24.82 | 21.49 | 23.41 | 16.05 | 19.87 | 19.37 | 9.64 | 21.74 | 15.74 |
| P₂O₅ | 0.00 | 0.00 | 0.00 | 0.00 | 0.00 | 0.00 | 0.00 | 0.00 | 0.00 |
| Li₂O | 0.00 | 0.00 | 0.00 | 0.00 | 0.00 | 0.00 | 0.00 | 0.00 | 0.00 |
| Na₂O | 0.04 | 0.04 | 0.05 | 0.05 | 0.08 | 0.07 | 0.10 | 0.06 | 0.02 |
| K₂O | 0.005 | 0.007 | 0.006 | 0.006 | 0.004 | 0.004 | 0.004 | 0.003 | 0.001 |
| MgO | 0.75 | 1.05 | 0.52 | 1.01 | 0.74 | 3.09 | 0.56 | 1.08 | 3.08 |
| CaO | 4.10 | 5.05 | 3.04 | 4.56 | 4.07 | 1.03 | 9.35 | 3.09 | 2.98 |
| SrO | 0.00 | 0.00 | 0.00 | 0.00 | 0.00 | 0.00 | 2.91 | 3.12 | 0.00 |
| BaO | 0.00 | 0.00 | 0.00 | 0.00 | 0.00 | 0.00 | 0.21 | 0.02 | 0.00 |
| TiO₂ | 0.000 | 0.000 | 0.000 | 0.000 | 0.000 | 0.000 | 0.000 | 0.008 | 0.000 |
| ZrO₂ | 0.001 | 0.000 | 0.000 | 0.000 | 0.000 | 0.000 | 0.000 | 0.000 | 0.000 |
| SnO₂ | 0.01 | 0.08 | 0.09 | 0.00 | 0.00 | 0.09 | 0.00 | 0.08 | 0.08 |
| Fe₂O₃ | 0.002 | 0.003 | 0.002 | 0.002 | 0.002 | 0.002 | 0.004 | 0.002 | 0.002 |
| B₂O₃ — Al₂O₃ | 20.42 | 16.41 | 16.85 | 8.07 | 11.36 | 13.29 | -1.05 | 17.07 | 11.75 |
| Li₂O + Na₂O + K₂O | 0.05 | 0.05 | 0.06 | 0.06 | 0.09 | 0.08 | 0.10 | 0.07 | 0.02 |
| MgO+CaO+SrO+BaO | 4.84 | 6.10 | 3.56 | 5.57 | 4.82 | 4.12 | 13.04 | 7.32 | 6.06 |
| (MgO+CaO+SrO+BaO)/(SiO₂+Al₂O₃+B₂O₃) | 0.051 | 0.065 | 0.037 | 0.059 | 0.051 | 0.043 | 0.150 | 0.079 | 0.065 |
| (MgO+CaO+SrO+BaO)/Al₂O₃ | 1.10 | 1.20 | 0.54 | 0.70 | 0.57 | 0.68 | 1.22 | 1.57 | 1.52 |
| (SrO+BaO)/B₂O₃ | 0.00 | 0.00 | 0.00 | 0.00 | 0.00 | 0.00 | 0.32 | 0.14 | 0.00 |
| B₂O₃—(MgO+CaO+SrO+BaO) | 20 | 15 | 20 | 10 | 15 | 15 | -3 | 14 | 10 |
| (SrO+BaO)/(MgO+CaO) | 0.0 | 0.0 | 0.0 | 0.0 | 0.0 | 0.0 | 0.3 | 0.8 | 0.0 |
| (B₂O₅—Al₂O₅)*(B₂O₃—(MgO+CaO+SrO+BaO)) | 408.0 | 252.6 | 334.4 | 84.5 | 170.9 | 202.7 | 3.6 | 246.2 | 113.7 |
| TiO₂+ZrO₂ | 0.001 | 0.000 | 0.000 | 0.000 | 0.000 | 0.000 | 0.000 | 0.008 | 0.000 |
| Density [g/cm³] | 2.176 | 2.218 | 2.194 | 2.255 | 2.439 | 2.203 | 2.458 | 2.279 | 2.219 |
| Ps [°C] | 539 | 582 | 557 | 624 | 598 | 589 | 668 | 583 | 616 |
| Ta [°C] | 599 | 642 | 622 | 685 | 659 | 660 | 723 | 637 | 696 |
| Ts [°C] | 938 | 964 | 960 | 974 | 987 | 1028 | 956 | Not measured | Not measured |
| 10^{4.0} dPa•s [°C] | 1334 | 1344 | 1316 | 1365 | 1296 | 1374 | 1284 | 1280 | 1434 |
| 10^{3.0} dPa•s [°C] | 1536 | 1539 | 1506 | 1549 | 1477 | 1569 | 1449 | 1478 | 1638 |
| 10^{2.5} dPa•s [°C] | 1659 | 1656 | 1624 | 1664 | 1588 | 1687 | 1555 | 1599 | 1774 |
| TL [°C] | 902.2 or less | 913.6 or less | 1344 | 1309 | 1274 | 1264 | 1098 | 960 | 1041.7 or less |
| log ηatTL [dPa•s] | 8.02 or higher | 8.24 or higher | 3.83 | 4.38 | 4.19 | 4.91 | 5.69 | 6.90 | 7.51 or higher |
| βOH [mm⁻¹] | Not measured | Not measured | Not measured | Not measured | Not measured | Not measured | 0.14 | Not measured | Not measured |

TABLE 2

| [mol%] | No. 1 | No. 2 | No. 3 | No. 4 | No. 5 | No. 6 | No. 7 | No. 8 | No. 9 |
|---|---|---|---|---|---|---|---|---|---|
| α(20-200)[×10⁻⁷/°C] | 33.3 | 31.4 | 30.4 | 26.2 | 28.7 | 26.9 | 36.2 | 34.1 | 26.9 |
| α(20-220)[×10⁻⁷/°C] | 33.2 | 31.4 | 30.4 | 26.2 | 28.8 | 26.8 | 36.6 | 34.1 | 26.9 |
| α(20-260)[×10⁻⁷/°C] | 33.0 | 31.3 | 30.3 | 26.2 | 28.8 | 26.8 | 37.2 | 34.0 | 26.7 |
| α(20-300)[×10⁻⁷/°C] | 32.7 | 31.2 | 30.1 | 25.9 | 28.7 | 26.6 | 37.6 | 33.9 | 26.6 |
| α(30-380)[×10⁻⁷/°C] | 32.1 | 30.9 | 29.6 | 25.9 | 28.7 | 26.2 | 38.6 | 33.7 | 26.2 |
| Young’s modulus [GPa] | 50 | 55 | 52 | 61 | 59 | 56 | 74 | 56 | Not measured |
| Rigidity modulus [GPa] | 20 | 22 | 21 | 25 | 24 | 23 | 30 | 23 | Not measured |
| Poisson’s ratio | 0.2 | 0.2 | 0.2 | 0.2 | 0.2 | 0.2 | 0.2 | 0.2 | Not measured |
| nd (measurement wavelength 587.6 nm) | Not measured | Not measured | Not measured | Not measured | Not measured | Not measured | 1.519 | Not measured | Not measured |
| nC (measurement wavelength 656.3 nm) | Not measured | Not measured | Not measured | Not measured | Not measured | Not measured | 1.516 | Not measured | Not measured |
| nF (measurement wavelength 486.1 nm) | Not measured | Not measured | Not measured | Not measured | Not measured | Not measured | 1.525 | Not measured | Not measured |
| ne (measurement wavelength 546.1 nm) | Not measured | Not measured | Not measured | Not measured | Not measured | Not measured | 1.521 | Not measured | Not measured |
| ng (measurement wavelength 435.8 nm) | Not measured | Not measured | Not measured | Not measured | Not measured | Not measured | 1.529 | Not measured | Not measured |
| nh (Measurement wavelength 404.7 nm) | Not measured | Not measured | Not measured | Not measured | Not measured | Not measured | 1.533 | Not measured | Not measured |
| ni (measurement wavelength 365.0 nm) | Not measured | Not measured | Not measured | Not measured | Not measured | Not measured | 1.539 | Not measured | Not measured |
| nF′ (measurement wavelength 480.0 nm) | Not measured | Not measured | Not measured | Not measured | Not measured | Not measured | 1.525 | Not measured | Not measured |
| LD785 (measurement wavelength 785 nm) | Not measured | Not measured | Not measured | Not measured | Not measured | Not measured | 1.513 | Not measured | Not measured |
| LD1310 (measurement wavelength 1310 nm) | Not measured | Not measured | Not measured | Not measured | Not measured | Not measured | 1.505 | Not measured | Not measured |
| LD1550 (measurement wavelength 1550 nm) | Not measured | Not measured | Not measured | Not measured | Not measured | Not measured | 1.503 | Not measured | Not measured |
| Abbe number vd | Not measured | Not measured | Not measured | Not measured | Not measured | Not measured | 62.5 | Not measured | Not measured |
| Relative dielectric constant 2.45 GHz | 4.09 | 4.26 | 4.14 | 4.40 | 4.35 | 4.11 | 5.36 | 4.38 | 4.15 |
| Dielectric loss tangent 2.45 GHz | 0.00090 | 0.00124 | 0.00098 | 0.00159 | 0.00145 | 0.00117 | 0.00338 | 0.00134 | 0.00112 |
| After 1000 hours at 85° C., 85% | | | | | | | | | |
| Relative dielectric constant 2.45 GHz | Not measured | Not measured | Not measured | Not measured | 4.30 | 4.11 | 5.35 | 4.38 | 4.16 |
| Dielectric loss tangent 2.45 GHz | Not measured | Not measured | Not measured | Not measured | 0.00150 | 0.00120 | 0.00347 | 0.00137 | 0.00117 |
| tanδ change rate [%] | Not measured | Not measured | Not measured | Not measured | 3.3 | 2.5 | 2.6 | 2.2 | 4.3 |
| After 2000 h at 85° C., 85% | | | | | | | | | |
| Dielectric constant 2.45 GHz | Not measured | Not measured | Not measured | Not measured | 4.31 | 4.11 | 5.35 | 4.37 | 4.15 |
| Dielectric loss tangent 2.45 GHz | Not measured | Not measured | Not measured | Not measured | 0.00150 | 0.00122 | 0.00352 | 0.00138 | 0.00116 |
| tanδ change rate [%] | Not measured | Not measured | Not measured | Not measured | 3.3 | 4.1 | 4.0 | 2.9 | 3.4 |
| HAST 120° C. 85% 12 h | | | | | | | | | |
| Relative dielectric constant 2.45 GHz | Not measured | Not measured | Not measured | Not measured | 4.33 | 4.10 | 5.35 | 4.37 | 4.16 |
| Dielectric loss tangent 2.45 GHz | Not measured | Not measured | Not measured | Not measured | 0.00147 | 0.00118 | 0.00348 | 0.00136 | 0.00114 |
| tanδ change rate [%] | Not measured | Not measured | Not measured | Not measured | 1.4 | 0.8 | 2.9 | 1.5 | 1.8 |
| HAST 120° C. 85% 48 h | | | | | | | | | |
| Relative dielectric constant 2.45 GHz | Not measured | Not measured | Not measured | Not measured | 4.33 | 4.11 | 5.37 | 4.37 | 4.15 |
| Dielectric loss tangent 2.45 GHz | Not measured | Not measured | Not measured | Not measured | 0.00148 | 0.00119 | 0.00337 | 0.00136 | 0.00115 |
| tanδ change rate [%] | Not measured | Not measured | Not measured | Not measured | 2.0 | -1.7 | 0.3 | 1.5 | 2.6 |

TABLE 3

| [mol%] | No. 10 | No. 11 | No. 12 | No. 13 | No. 14 | No. 15 | No. 16 | No. 17 | No. 18 |
|---|---|---|---|---|---|---|---|---|---|
| SiO₂ | 67.24 | 68.54 | 70.17 | 65.01 | 63.64 | 69.30 | 67.84 | 68.83 | 68.85 |
| Al₂O₃ | 6.52 | 4.44 | 4.36 | 6.48 | 8.62 | 8.12 | 8.21 | 4.43 | 4.46 |
| B₂O₃ | 21.32 | 22.16 | 20.64 | 23.62 | 22.79 | 16.92 | 18.27 | 23.87 | 23.85 |
| P₂O₅ | 0.00 | 0.00 | 0.00 | 0.00 | 0.00 | 0.00 | 0.00 | 0.00 | 0.00 |
| Li₂O | 0.00 | 0.00 | 0.00 | 0.00 | 0.00 | 0.00 | 0.00 | 0.00 | 0.00 |
| Na₂O | 0.04 | 0.02 | 0.02 | 0.03 | 0.04 | 0.04 | 0.04 | 0.02 | 0.02 |
| K₂O | 0.001 | 0.001 | 0.001 | 0.001 | 0.002 | 0.002 | 0.001 | 0.002 | 0.002 |
| MgO | 0.77 | 0.76 | 0.76 | 0.75 | 0.78 | 1.06 | 1.06 | 2.80 | 0.03 |
| CaO | 4.11 | 4.08 | 4.05 | 4.10 | 4.13 | 4.55 | 4.58 | 0.05 | 2.78 |
| SrO | 0.00 | 0.00 | 0.00 | 0.00 | 0.00 | 0.00 | 0.00 | 0.00 | 0.00 |
| BaO | 0.00 | 0.00 | 0.00 | 0.00 | 0.00 | 0.00 | 0.00 | 0.00 | 0.00 |
| TiO₂ | 0.000 | 0.000 | 0.000 | 0.000 | 0.001 | 0.000 | 0.000 | 0.000 | 0.000 |
| ZrO₂ | 0.000 | 0.000 | 0.000 | 0.000 | 0.001 | 0.000 | 0.000 | 0.000 | 0.000 |
| SnO₂ | 0.00 | 0.00 | 0.00 | 0.00 | 0.00 | 0.00 | 0.00 | 0.00 | 0.00 |
| Fe₂O₃ | 0.002 | 0.002 | 0.002 | 0.002 | 0.002 | 0.002 | 0.002 | 0.002 | 0.002 |
| B₂O₃ - Al₂O₃ | 14.80 | 17.72 | 16.27 | 17.14 | 14.17 | 8.79 | 10.06 | 19.44 | 19.39 |
| Li₂O + Na₂O + K₂O | 0.04 | 0.02 | 0.02 | 0.03 | 0.04 | 0.04 | 0.04 | 0.02 | 0.02 |
| MgO+CaO+SrO+BaO | 4.88 | 4.84 | 4.80 | 4.85 | 4.91 | 5.61 | 5.64 | 2.84 | 2.81 |
| (MgO+CaO+SrO+BaO)/(SiO₂+AL₂O₃+B₂O₃) | 0.051 | 0.051 | 0.050 | 0.051 | 0.052 | 0.059 | 0.060 | 0.029 | 0.029 |
| (MgO+CaO+SrO+BaO)/Al₂O₃ | 0.75 | 1.09 | 1.10 | 0.75 | 0.57 | 0.69 | 0.69 | 0.64 | 0.63 |
| (SrO+BaO)/B₂O₃ | 0.00 | 0.00 | 0.00 | 0.00 | 0.00 | 0.00 | 0.00 | 0.00 | 0.00 |
| B₂O₃-(MgO+CaO+SrO+BaO) | 16 | 17 | 16 | 19 | 18 | 11 | 13 | 21 | 21 |
| (SrO+BaO)/(MgO+CaO) | 0.0 | 0.0 | 0.0 | 0.0 | 0.0 | 0.0 | 0.0 | 0.0 | 0.0 |
| (B₂O₃-Al₂O₃)*(B₂O₃-(MgO+CaO+SrO+BaO)) | 243.4 | 306.9 | 257.7 | 321.8 | 253.4 | 99.5 | 126.9 | 408.7 | 408.0 |
| TiO₂+ZrO₂ | 0.000 | 0.000 | 0.000 | 0.000 | 0.001 | 0.000 | 0.000 | 0.000 | 0.000 |
| Density [g/cm³] | 2.207 | 2.185 | 2.190 | 2.198 | 2.227 | 2.250 | 2.245 | 2.145 | 2.152 |
| Ps [°C] | 582 | 561 | 573 | 567 | 585 | 623 | 616 | 520 | 534 |
| Ta [°C] | 640 | 622 | 636 | 624 | 640 | 682 | 674 | 596 | 598 |
| Ts [°C] | Not measured | Not measured | Not measured | Not measured | 963 | Not measured | Not measured | Not measured | 926 |
| 10^{4.0} dPa•s [°C] | 1316 | 1358 | 1385 | 1279 | 1252 | 1334 | 1309 | 1348 | 1369 |
| 10^{3.0} dPa•s [°C] | 1507 | 1564 | 1588 | 1468 | 1428 | 1521 | 1491 | 1551 | 1579 |
| 10^{2.5} dPa•s [°C] | 1625 | 1678 | 1717 | 1583 | 1539 | 1634 | 1603 | 1670 | 1706 |
| TL [°C] | 1150 | 913 | 913.6 or less | 1125 | 1264 | 1222 | 1220 | 1218.5 or greater | 1216 |
| log ηatTL [dPa•s] | 5.26 | 7.88 | 8.15 or greater | 5.20 | 3.92 | 4.87 | 4.70 | 4.93 or less | 4.96 |
| βOH [mm⁻¹] | Not measured | Not measured | Not measured | Not measured | Not measured | Not measured | Not measured | Not measured | Not measured |

TABLE 4

| [mol%] | No. 10 | No. 11 | No. 12 | No. 13 | No. 14 | No. 15 | No. 16 | No. 17 | No. 18 |
|---|---|---|---|---|---|---|---|---|---|
| α(20-200)[×10⁻⁷/°C] | 30.1 | 31.4 | 30.3 | 32.0 | 30.9 | 27.2 | 28.2 | 30.8 | 31.5 |
| α(20-220)[×10⁻⁷/°C] | 30.1 | 31.3 | 30.2 | 31.9 | 31.0 | 27.3 | 28.3 | 30.6 | 31.4 |
| α(20-260)[×10⁻⁷/°C] | 30.0 | 31.1 | 30.0 | 31.8 | 31.0 | 27.4 | 28.4 | 30.3 | 31.1 |
| α(20-300)[×10⁻⁷/°C] | 29.9 | 30.9 | 29.8 | 31.7 | 31.0 | 27.5 | 28.4 | 29.9 | 30.7 |
| α(30-380)[×10⁻⁷/°C] | 29.6 | 30.3 | 29.2 | 31.3 | 30.9 | 27.6 | 28.4 | 29.1 | 29.9 |
| Young’s modulus [GPa] | 54 | 52 | Not measured | 52 | 56 | 60 | 59 | 48 | 48 |
| Rigidity modulus [GPa] | 22 | 21 | Not measured | 21 | 23 | 25 | 24 | 20 | 20 |
| Poisson’s ratio | 0.2 | 0.2 | Not measured | 0.2 | 0.2 | 0.2 | 0.2 | 0.2 | 0.2 |
| nd (measurement wavelength 587.6 nm) | Not measured | Not measured | Not measured | Not measured | Not measured | Not measured | Not measured | Not measured | Not measured |
| nC (measurement wavelength 656.3 nm) | Not measured | Not measured | Not measured | Not measured | Not measured | Not measured | Not measured | Not measured | Not measured |
| nF (measurement wavelength 486.1 nm) | Not measured | Not measured | Not measured | Not measured | Not measured | Not measured | Not measured | Not measured | Not measured |
| ne (measurement wavelength 546.1 nm) | Not measured | Not measured | Not measured | Not measured | Not measured | Not measured | Not measured | Not measured | Not measured |
| ng (measurement wavelength 435.8 nm) | Not measured | Not measured | Not measured | Not measured | Not measured | Not measured | Not measured | Not measured | Not measured |
| nh (Measurement wavelength 404.7 nm) | Not measured | Not measured | Not measured | Not measured | Not measured | Not measured | Not measured | Not measured | Not measured |
| ni (measurement wavelength 365.0 nm) | Not measured | Not measured | Not measured | Not measured | Not measured | Not measured | Not measured | Not measured | Not measured |
| nF′ (measurement wavelength 480.0 nm) | Not measured | Not measured | Not measured | Not measured | Not measured | Not measured | Not measured | Not measured | Not measured |
| LD785 (measurement wavelength 785 nm) | Not measured | Not measured | Not measured | Not measured | Not measured | Not measured | Not measured | Not measured | Not measured |
| LD1310 (measurement wavelength 1310 nm) | Not measured | Not measured | Not measured | Not measured | Not measured | Not measured | Not measured | Not measured | Not measured |
| LD1550 (measurement wavelength 1550 nm) | Not measured | Not measured | Not measured | Not measured | Not measured | Not measured | Not measured | Not measured | Not measured |
| Abbe number vd | Not measured | Not measured | Not measured | Not measured | Not measured | Not measured | Not measured | Not measured | Not measured |
| Relative dielectric constant 2.45 GHz | 4.22 | 4.11 | 4.12 | 4.19 | 4.32 | 4.39 | 4.38 | 3.90 | 3.98 |
| Dielectric loss tangent 2.45 GHz | 0.00118 | 0.00095 | 0.00095 | 0.00109 | 0.00131 | 0.00158 | 0.00150 | 0.00070 | 0.00072 |
| After 1000 hours at 85° C., 85% | | | | | | | | | |
| Relative dielectric constant 2.45 GHz | 4.16 | 4.11 | 4.11 | 4.20 | 4.32 | 4.39 | 4.37 | 3.91 | 4.02 |
| Dielectric loss tangent 2.45 GHz | 0.00115 | 0.00122 | 0.00113 | 0.00141 | 0.00139 | 0.00158 | 0.00151 | 0.00196 | 0.00303 |
| tanδ change rate [%] | -2.6 | 22.0 | 16.0 | 22.7 | 5.8 | 0.0 | 0.7 | 64.5 | 76.2 |
| After 2000 h at 85° C., 85% | | | | | | | | | |
| Dielectric constant 2.45 GHz | 4.16 | 4.11 | 4.12 | 4.20 | 4.32 | 4.39 | 4.37 | 3.92 | 4.04 |
| Dielectric loss tangent 2.45 GHz | 0.00115 | 0.00128 | 0.00117 | 0.00153 | 0.00141 | 0.00156 | 0.00150 | 0.00212 | 0.00396 |
| tanδ change rate [%] | -2.6 | 25.7 | 18.9 | 28.8 | 7.1 | -1.3 | 0.0 | 67.2 | 81.8 |
| HAST 120° C. 85% 12 h | | | | | | | | | |
| Relative dielectric constant 2.45 GHz | 4.22 | 4.10 | 4.11 | 4.20 | 4.31 | 4.38 | 4.37 | 3.90 | 3.98 |
| Dielectric loss tangent 2.45 GHz | 0.00121 | 0.00103 | 0.00099 | 0.00118 | 0.00132 | 0.00159 | 0.00150 | 0.00120 | 0.00121 |
| tanδ change rate [%] | 2.5 | 7.7 | 4.2 | 7.6 | 0.8 | 0.6 | 0.0 | 42.0 | 40.3 |
| HAST 120° C. 85% 48 h | | | | | | | | | |
| Relative dielectric constant 2.45 GHz | 4.22 | 4.11 | 4.11 | 4.20 | 4.32 | 4.38 | 4.37 | 3.90 | 3.98 |
| Dielectric loss tangent 2.45 GHz | 0.00125 | 0.00108 | 0.00104 | 0.00126 | 0.00135 | 0.00163 | 0.00149 | 0.00130 | 0.00154 |
| tanδ change rate [%] | 5.6 | 11.9 | 8.7 | 13.5 | 3.0 | 3.1 | -0.7 | 46.5 | 53.1 |

TABLE 5

| [mol%] | No. 19 | No. 20 | No. 21 | No. 22 | No. 23 | No. 24 | No. 25 | No. 26 | No. 27 | No. 28 |
|---|---|---|---|---|---|---|---|---|---|---|
| SiO₂ | 68.66 | 68.83 | 67.06 | 67.26 | 67.39 | 68.08 | 65.37 | 66.50 | 81.67 | 71.69 |
| Al₂O₃ | 4.43 | 4.39 | 4.43 | 4.45 | 4.42 | 4.43 | 3.96 | 4.91 | 1.40 | 14.30 |
| B₂O₃ | 23.99 | 23.90 | 23.52 | 23.34 | 23.24 | 22.46 | 26.59 | 24.54 | 12.55 | 0.00 |
| P₂O₅ | 0.00 | 0.00 | 0.00 | 0.00 | 0.00 | 0.00 | 0.00 | 0.00 | 0.00 | 0.65 |
| Li₂O | 0.00 | 0.00 | 0.00 | 0.00 | 0.00 | 0.00 | 0.00 | 0.00 | 0.00 | 8.13 |
| Na₂O | 0.03 | 0.03 | 0.03 | 0.03 | 0.02 | 0.03 | 0.01 | 0.009 | 4.39 | 0.42 |
| K₂O | 0.002 | 0.003 | 0.001 | 0.003 | 0.002 | 0.001 | 0.003 | 0.009 | 0.000 | 0.209 |
| MgO | 0.00 | 0.00 | 3.82 | 0.08 | 0.00 | 1.19 | 1.00 | 0.99 | 0.00 | 1.14 |
| CaO | 0.04 | 0.02 | 0.02 | 4.83 | 0.02 | 0.01 | 2.98 | 2.94 | 0.00 | 0.00 |
| SrO | 2.82 | 0.01 | 0.01 | 0.00 | 4.87 | 0.01 | 0.00 | 0.004 | 0.00 | 0.00 |
| BaO | 0.02 | 2.81 | 1.10 | 0.00 | 0.03 | 3.79 | 0.00 | 0.00 | 0.00 | 0.51 |
| TiO₂ | 0.007 | 0.000 | 0.000 | 0.000 | 0.000 | 0.001 | 0.004 | 0.000 | 0.000 | 1.644 |
| ZrO₂ | 0.001 | 0.000 | 0.000 | 0.000 | 0.000 | 0.000 | 0.002 | 0.000 | 0.000 | 1.172 |
| SnO₂ | 0.00 | 0.00 | 0.00 | 0.00 | 0.00 | 0.00 | 0.09 | 0.09 | 0.00 | 0.13 |
| Fe₂O₃ | 0.001 | 0.001 | 0.002 | 0.002 | 0.002 | 0.001 | 0.000 | 0.002 | 0.000 | 0.000 |
| B₂O₃ — Al₂O₃ | 19.55 | 19.51 | 19.09 | 18.89 | 18.82 | 18.03 | 22.63 | 19.63 | 11.15 | -14.30 |
| Li₂O + Na₂O + K₂O | 0.03 | 0.04 | 0.03 | 0.03 | 0.02 | 0.03 | 0.01 | 0.02 | 4.39 | 8.76 |
| MgO+CaO+SrO+BaO | 2.88 | 2.84 | 4.96 | 4.90 | 4.92 | 5.00 | 3.98 | 3.93 | 0.00 | 1.65 |
| (MgO+CaO+SrO+BaO)/(SiO₂+Al₂O₃+ B₂O₃) | 0.030 | 0.029 | 0.052 | 0.052 | 0.052 | 0.053 | 0.042 | 0.041 | 0.000 | 0.019 |
| (MgO+CaO+SrO+BaO)/Al₂O₃ | 0.65 | 0.65 | 1.12 | 1.10 | 1.11 | 1.13 | 1.01 | 0.80 | 0.00 | 0.12 |
| (SrO+BaO)/B₂O₃ | 0.12 | 0.12 | 0.05 | 0.00 | 0.21 | 0.17 | 0.00 | 0.00 | 0.00 | |
| B₂O₃—(MgO+CaO+SrO+BaO) | 21 | 21 | 19 | 18 | 18 | 17 | 23 | 21 | 13 | -2 |
| (SrO+BaO)/(MgO+CaO) | 81.2 | 118.0 | 0.3 | 0.0 | 207.2 | 3.2 | 0.0 | 0.0 | | 0.5 |
| (B₂O₃—Al₂O₃)*(B₂O₃—(MgO+CaO+SrO+BaO)) | 412.7 | 411.0 | 354.4 | 348.2 | 344.6 | 314.7 | 511.5 | 404.5 | 139.9 | 23.7 |
| TiO₂+ZrO₂ | 0.008 | 0.000 | 0.000 | 0.000 | 0.000 | 0.001 | 0.006 | 0.000 | 0.000 | 2.817 |
| Density [g/cm³] | 2.189 | 2.221 | 2.196 | 2.185 | 2.253 | 2.275 | 2.156 | 2.171 | 2.231 | 2.430 |
| Ps [°C] | 525 | 518 | 549 | 562 | 547 | 536 | 510 | 540 | 499 | 655 |
| Ta [°C] | 588 | 580 | 611 | 620 | 605 | 594 | 573 | 601 | 548 | 711 |
| Ts [°C] | 927 | 943 | Not measured | Not measured | 903 | 899 | Not measured | Not measured | 793 | Not measured |
| 10^{4.0} dPa•s [°C] | 1373 | 1379 | 1333 | 1334 | 1330 | 1340 | 1307 | 1313 | 1194 | 1328 |
| 10^{3.0} dPa•s [°C] | 1586 | 1596 | 1531 | 1536 | 1539 | 1550 | 1509 | 1510 | 1443 | 1509 |
| 10^{2.5} dPa•s [°C] | 1712 | 1728 | 1652 | 1654 | 1666 | 1670 | 1634 | 1636 | Not measured | 1621 |
| TL [°C] | 1203 | 1200 | 1111 | 1073.1 or less | 1058.8 or less | 1073.1 or less | 924 | Not measured | Not measured | Not measured |
| log ηatTL [dPa·s] | 5.08 | 5.18 | 5.66 | 5.98 or greater | 5.94 or greater | 5.83 or greater | 7.2 | Not measured | Not measured | Not measured |
| βOH [mm⁻¹] | Not measured | Not measured | Not measured | Not measured | Not measured | Not measured | 0.36 | 0.45 | Not measured | Not measured |

TABLE 6

| [mol%] | No. 19 | No. 20 | No. 21 | No. 22 | No. 23 | No. 24 | No. 25 | No. 26 | No. 27 | No. 28 |
|---|---|---|---|---|---|---|---|---|---|---|
| α(20-200)[×10⁻⁷/°C] | 32.4 | 33.4 | 31.8 | 32.6 | 34.4 | 34.4 | 33.5 | 32.1 | Not measured | Not measured |
| α(20-220)[×10⁻⁷/°C] | 32.3 | 33.2 | 31.7 | 32.5 | 34.3 | 34.4 | 33.4 | 32.0 | Not measured | Not measured |
| α(20-260)[×10⁻⁷/°C] | 32.0 | 32.9 | 31.4 | 32.3 | 34.1 | 34.2 | 33.1 | 31.8 | Not measured | Not measured |
| α(20-300)[×10⁻⁷/°C] | 31.6 | 32.6 | 31.2 | 32.0 | 33.8 | 33.9 | 32.8 | 31.5 | Not measured | Not measured |
| α(30-380)[×10⁻⁷/°C] | 30.8 | 31.8 | 30.5 | 31.5 | 33.3 | 33.3 | 32.1 | 30.9 | 35.0 | 40.0 |
| Young’s modulus [GPa] | 48 | 47 | 50 | 51 | 50 | 50 | 50 | 49 | 73 | 85% |
| Rigidity modulus [GPa] | 20 | 19 | 20 | 21 | 21 | 20 | 20 | 20 | Not measured | Not measured |
| Poisson’s ratio | 0.2 | 0.2 | 0.2 | 0.2 | 0.2 | 0.2 | 0.2 | 0.2 | Not measured | Not measured |
| nd (measurement wavelength 587.6 nm) | Not measured | Not measured | Not measured | Not measured | Not measured | Not measured | 1.476 | 1.478 | Not measured | Not measured |
| nC (measurement wavelength 656.3 nm) | Not measured | Not measured | Not measured | Not measured | Not measured | Not measured | 1.474 | 1.475 | Not measured | Not measured |
| nF (measurement wavelength 486.1 nm) | Not measured | Not measured | Not measured | Not measured | Not measured | Not measured | 1.482 | 1.483 | Not measured | Not measured |
| ne (measurement wavelength 546.1 nm) | Not measured | Not measured | Not measured | Not measured | Not measured | Not measured | 1.478 | 1.479 | Not measured | Not measured |
| ng (measurement wavelength 435.8 nm) | Not measured | Not measured | Not measured | Not measured | Not measured | Not measured | 1.486 | 1.487 | Not measured | Not measured |
| nh (Measurement wavelength 404.7 nm) | Not measured | Not measured | Not measured | Not measured | Not measured | Not measured | 1.489 | 1.490 | Not measured | Not measured |
| ni (measurement wavelength 365.0 nm) | Not measured | Not measured | Not measured | Not measured | Not measured | Not measured | 1.494 | 1.496 | Not measured | Not measured |
| nF′ (measurement wavelength 480.0 nm) | Not measured | Not measured | Not measured | Not measured | Not measured | Not measured | 1.482 | 1.483 | Not measured | Not measured |
| LD785 (measurement wavelength 785 nm) | Not measured | Not measured | Not measured | Not measured | Not measured | Not measured | 1.471 | 1.472 | Not measured | Not measured |
| LD1310 (measurement wavelength 1310 nm) | Not measured | Not measured | Not measured | Not measured | Not measured | Not measured | 1.463 | 1.465 | Not measured | Not measured |
| LD1550 (measurement wavelength 1550 nm) | Not measured | Not measured | Not measured | Not measured | Not measured | Not measured | 1.460 | 1.461 | Not measured | Not measured |
| Abbe number vd | Not measured | Not measured | Not measured | Not measured | Not measured | Not measured | 63.3 | 63.4 | Not measured | Not measured |
| Relative dielectric constant 2.45 GHz | 4.02 | 4.08 | 4.05 | 4.14 | 4.21 | 4.25 | 4.00 | 4.06 | 4.54 | 6.24 |
| Dielectric loss tangent 2.45 GHz | 0.00073 | 0.00076 | 0.00095 | 0.00097 | 0.00092 | 0.00097 | 0.00072 | 0.00085 | 0.00591 | 0.00522 |
| After 1000 hours at 85° C., 85% | | | | | | | | | | |
| Relative dielectric constant 2.45 GHz | 4.08 | 4.13 | 4.06 | 4.15 | 4.22 | 4.27 | 4.02 | Not measured | 4.53 | 6.22 |
| Dielectric loss tangent 2.45 GHz | 0.00396 | 0.00224 | 0.00133 | 0.00139 | 0.00173 | 0.00227 | 0.00326 | Not measured | 0.00595 | 0.00522 |
| tanδ change rate [%] | 81.6 | 66.1 | 28.9 | 30.2 | 46.6 | 57.4 | 77.8 | Not measured | 0.7 | 0.0 |
| After 2000 h at 85° C., 85% | | | | | | | | | | |
| Dielectric constant 2.45 GHz | 4.14 | 4.18 | 407 | 4.15 | 4.23 | 4.28 | 4.04 | Not measured | 4.53 | 6.24 |
| Dielectric loss tangent 2.45 GHz | 0.00642 | 0.00551 | 0.00141 | 0.00150 | 0.00197 | 0.00266 | 0.00427 | Not measured | 0.00598 | 0.00519 |
| tanδ change rate [%] | 88.6 | 86.2 | 32.9 | 35.3 | 53.1 | 636 | 83.1 | Not measured | 1.2 | 0.6 |
| HAST 120° C. 85% 12 h | | | | | | | | | | |
| Relative dielectric constant 2.45 GHz | 4.02 | 4.09 | 4.05 | 4.14 | 4.21 | 4.25 | 3.99 | 4.04 | 4.54 | 6.24 |
| Dielectric loss tangent 2.45 GHz | 0.00146 | 0.00198 | 0.00112 | 0.00110 | 0.00114 | 0.00135 | 0.00122 | 0.00101 | 0.00595 | 0.00522 |
| tanδ change rate [%] | 50.1 | 61.6 | 15.5 | 11.8 | 19.0 | 28.3 | 40.7 | 15.7 | 0.7 | 0.0 |
| HAST 120° C. 85% 48 h | | | | | | | | | | |
| Relative dielectric constant 2.45 GHz | 4.03 | 4.10 | 4.06 | 4.14 | 4.22 | 426 | 4.01 | 4.07 | 4.54 | 6.22 |
| Dielectric loss tangent 2.45 GHz | 0.00199 | 0.00230 | 0.00117 | 0.00116 | 0.00125 | 0.00150 | 0.00108 | 0.00123 | 0.00593 | 0.00521 |
| tanδ change rate [%] | 63.4 | 67.0 | 19.1 | 16.4 | 26.2 | 35.5 | 33.1 | 30.8 | 0.3 | -0.2 |

Sample Nos. 1 to 28 were prepared as follows. First, glass raw materials compounded according to the composition indicated in the tables were placed into a platinum crucible and melted at 1650° C. for 24 hours. The molten material was then poured over a carbon plate and formed into a flat sheet shape. The glass of Sample No. 28 was heated at 770° C. for 3 hours and subjected to a crystal nucleation process, after which a crystal growth process was carried out by heating at 880° C. for 1 hour, and the glass was crystallized. Next, each obtained sample was held at a temperature of the annealing point plus 30° C. for 30 minutes, and then cooled to room temperature at a rate of -3° C./min. After that, each obtained sample was evaluated for the density, strain point Ps, annealing point Ta, softening point Ts, the temperature at 10^{4.0} dPa·s, the temperature at 10^{3.0} dPa·s, the temperature at 10^{2.5} dPa·s, the liquid phase temperature TL, the liquid phase viscosity logηTL, the β—OH value, the thermal expansion coefficient α, the Young’s modulus, the rigidity modulus, Poisson’s ratio, the relative dielectric constant at 25° C. and a frequency of 2.45 GHz, the dielectric loss tangent at 25° C. and a frequency 2.45 GHz, and, after a constant temperature/constant humidity test and a constant high-temperature/constant high-humidity test at various test conditions, the relative dielectric constant at 25° C. and a frequency of 2.45 GHz and the dielectric loss tangent at 25° C. and a frequency 2.45 GHz.

The density is a value measured by the well-known Archimedes method.

The strain point Ps, the annealing point Ta, and the softening point Ts are values measured in accordance with methods specified in ASTM C336 and C338.

The temperature at 10^{4.0} dPa·s, the temperature at 10^{3.0} dPa·s, and the temperature at 10^{2.5} dPa·s are values measured by a platinum sphere pull up method.

The liquidus temperature TL is a value obtained by measuring a temperature at which crystals are precipitated after glass powder that passed through a standard 30-mesh sieve (500 µm) and remained on a 50-mesh sieve (300 µm) is placed in a platinum boat and then kept for 24 hours in a gradient heating furnace.

The liquidus viscosity logηTL is a value obtained by measuring a glass viscosity at the liquidus temperature TL using the platinum sphere pull up method.

The β—OH value is a value measured by the method described above.

The thermal expansion coefficient α is a value measured by a dilatometer, and is an average value in the indicated temperature range.

The Young’s modulus and rigidity modulus are values measured by a resonance method. The Poisson ratio is a value calculated from these values.

The refractive indices (nd, nC, nF, ne, ng, nh, ni, nF′, LD785, LD1310, LD1550) are values measured using a well-known V block method, and can be measured using, for example, a commercially available refractive index meter KPR-2000 (available from Shimadzu Corporation). The value for the Abbe number vd was obtained from the equation (nd-1)/(nF-nC).

The relative dielectric constant and dielectric loss tangent at 25° C. and a frequency of 2.45 GHz are values measured by a well-known cavity resonator method. Note that the frequency of 2.45 GHz is the resonance frequency of the air in the cavity resonator.

The constant temperature/constant humidity test was carried out using a commercially available constant high-temperature/constant high-humidity tester for a test time of 1000 hours under conditions including a temperature of 85° C. and a relative humidity of 85%. The rate of change of the dielectric loss tangent (tanδ change rate) was calculated from the equation of [(dielectric loss tangent after test - dielectric loss tangent before test)/(dielectric loss tangent after test)] x 100.

The constant high-temperature/constant high-humidity test was carried out using a commercially available constant high-temperature/constant high-humidity tester for a test time of 12 hours or 48 hours under conditions including a temperature of 120° C. and a relative humidity of 85% with reference to the conditions set forth in JIS-C0096-2001. The rate of change of the dielectric loss tangent (tanδ change rate) was calculated by the equation of [(dielectric loss tangent after test - dielectric loss tangent before test)/(dielectric loss tangent after test)] x 100.

With Sample Nos. 1 to 16, 21, 26, 27, and 28, the dielectric loss tangent at a measurement frequency of 2.45 GHz and a measurement temperature of 25° C. did not change much after the constant temperature/constant humidity test and constant high-temperature/constant high-humidity test. However, with Sample Nos. 17 to 20 and 22 to 25, the dielectric loss tangents at the measurement frequency of 2.45 GHz and measurement temperature of 25° C. changed much.

### Example 2

Each sample in the constant temperature/constant humidity test and constant high-temperature/constant high-humidity test was subjected to various heating treatments. The results are shown in Table 7 to 9.

TABLE 7

| | No. 1 | No. 2 | No. 3 | No. 4 | No. 5 | No. 6 | No. 7 | No. 8 | No. 9 |
|---|---|---|---|---|---|---|---|---|---|
| Drying at 100° C., 24 h | | | | | | | | | |
| Relative dielectric constant 2.45 GHz | Not measured | Not measured | Not measured | Not measured | 4.34 | 4.10 | 5.35 | 4.37 | 4.15 |
| Dielectric loss tangent 2.45 GHz | Not measured | Not measured | Not measured | Not measured | 0.00148 | 0.00118 | 0.00347 | 0.00138 | 0.00116 |
| Anneal at Ta+30° C., 30 min | | | | | | | | | |
| Relative dielectric constant 2.45 GHz | Not measured | Not measured | Not measured | Not measured | Not measured | Not measured | Not measured | Not measured | Not measured |
| Dielectric loss tangent 2.45 GHz | Not measured | Not measured | Not measured | Not measured | Not measured | Not measured | Not measured | Not measured | Not measured |
| Anneal at Ta+30° C., 3 h | | | | | | | | | |
| Relative dielectric constant 2.45 GHz | Not measured | Not measured | Not measured | Not measured | 4.33 | 4.10 | 5.34 | 4.38 | 4.15 |
| Dielectric loss tangent 2.45 GHz | Not measured | Not measured | Not measured | Not measured | 0.00142 | 0.00114 | 0.00345 | 0.00133 | 0.00114 |

TABLE 8

| | No. 10 | No. 11 | No. 12 | No. 13 | No. 14 | No. 15 | No. 16 | No. 17 | No. 18 |
|---|---|---|---|---|---|---|---|---|---|
| Drying at 100° C., 24 h | | | | | | | | | |
| Relative dielectric constant 2.45 GHz | 4.22 | 4.10 | 4.11 | 4.20 | 4.32 | 4.38 | 4.37 | 3.90 | 3.98 |
| Dielectric loss tangent 2.45 GHz | 0.00127 | 0.00109 | 0.00108 | 0.00124 | 0.00136 | 0.00159 | 0.00150 | 0.00130 | 0.00152 |
| Anneal at Ta+30° C., 30 min | | | | | | | | | |
| Relative dielectric constant 2.45 GHz | Not measured | Not measured | Not measured | Not measured | Not measured | Not measured | 4.38 | Not measured | Not measured |
| Dielectric loss tangent 2.45 GHz | Not measured | Not measured | Not measured | Not measured | Not measured | Not measured | 0.00147 | Not measured | Not measured |
| Anneal at Ta+30° C., 3 h | | | | | | | | | |
| Relative dielectric constant 2.45 GHz | 4.22 | 4.10 | 4.10 | 4.19 | 4.32 | 4.38 | 4.37 | 3.89 | 3.96 |
| Dielectric loss tangent 2.45 GHz | 0.00116 | 0.00097 | 0.00095 | 0.00110 | 0.00128 | 0.00153 | 0.00144 | 0.00084 | 0.00074 |

TABLE 9

| | No. 19 | No. 20 | No. 21 | No. 22 | No. 23 | No. 24 | No. 25 | No. 26 | No. 27 | No. 28 |
|---|---|---|---|---|---|---|---|---|---|---|
| Drying at 100° C., 24 h | | | | | | | | | | |
| Relative dielectric constant 2.45 GHz | 403 | 4.10 | 4.05 | 4.14 | 4.21 | 4.26 | 3.99 | Not measured | 4.54 | 6.22 |
| Dielectric loss tangent 2.45 GHz | 0.00192 | 0.00224 | 0.00117 | 0.00116 | 0.00124 | 0.00150 | 0.00138 | Not measured | 0.00589 | 0.00526 |
| Anneal at Ta+30° C., 30 min | | | | | | | | | | |
| Relative dielectric constant 2.45 GHz | Not measured | 4.06 | Not measured | Not measured | Not measured | Not measured | 3.98 | Not measured | Not measured | Not measured |
| Dielectric loss tangent 2.45 GHz | Not measured | 0.00082 | Not measured | Not measured | Not measured | Not measured | 0.00096 | Not measured | Not measured | Not measured |
| Anneal at Ta+30° C., 3 h | | | | | | | | | | |
| Relative dielectric constant 2.45 GHz | 400 | 4.06 | 4.05 | 4.13 | 4.21 | 424 | 3.98 | 403 | 4.52 | 6.21 |
| Dielectric loss tangent 2.45 GHz | 0.00076 | 0.00079 | 0.00100 | 0.00100 | 0.00094 | 0.00100 | 0.00078 | 0.00085 | 0.00579 | 0.00522 |

First, the sample was dried at 100° C. for 24 hours, after which the dielectric loss tangent was measured at a measurement frequency of 2.45 GHz and a measurement temperature of 25° C. The dielectric loss tangent was almost unchanged.

Next, for each sample after the constant temperature/constant humidity test and the constant high-temperature/constant high-humidity test, the sample was held for 30 minutes or 3 hours at a temperature of the annealing point of each sample plus 30° C., after which the sample was cooled to room temperature at a rate of -3° C./min. After that, the dielectric loss tangent was measured at a measurement frequency of 2.45 GHz and a measurement temperature of 25° C.

As is clear from Tables 4 to 6, with Sample Nos. 1 to 28, as the heating time became longer, there was a tendency for the dielectric loss tangent to approach the value prior to the constant temperature/constant humidity test and the constant high-temperature/constant high-humidity test. From this and through measurements of the dielectric properties, it is understood that for a case in which the dielectric properties of the measurement standard material are changed, the dielectric properties of the material can be restored to the initial dielectric properties when a predetermined heating treatment is implemented.

### Example 3

Sample Nos. 7, 25, and 26 were subjected to the following experiment in order to investigate the mechanism of change in the dielectric loss tangent.

First, for Sample Nos. 7 and 25, the X-ray intensity of boron in a cross-section of glass was analyzed before and after a constant high-temperature/constant high-humidity test under conditions including a temperature of 120° C., a relative humidity of 85%, and a test time of 48 hours. Furthermore, Sample No. 25 was held for 3 hours at a temperature of the annealing point plus 30° and then cooled to room temperature at a rate of -3° C./min, after which the X-ray intensity of boron in a cross-section of the glass was analyzed.

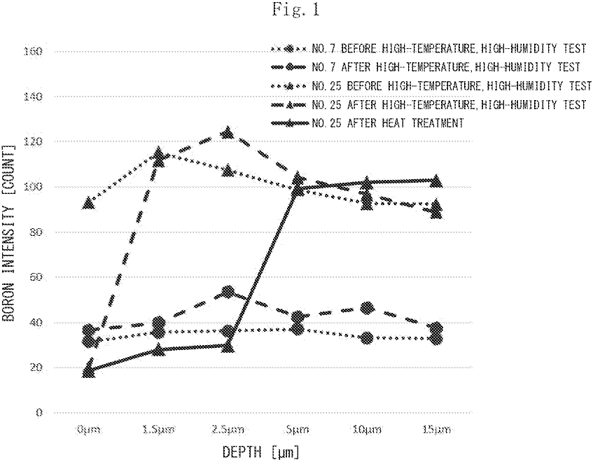

Here, the X-ray intensity distribution of boron in the depth direction of the cross section was analyzed using an electron probe micro analyzer (EPMA) (EPMA-1720, available from Shimadzu Corporation). The cut surface of the glass before and after the heat treatment was used as an analysis sample, and spot analysis for the characteristic X-ray intensity value (unit: count) of the Kα line of the boron element was conducted at positions (depths) of 0 µm, 1.5 µm, 2.5 µm, 5 µm, 10 µm, and 15 µm in the depth direction from the glass outermost surface, and the distribution of the X-ray intensity of boron in the depth direction of the glass was confirmed. Here, regarding the outermost surface, that is, a depth of 0 µm, when the cut surface was measured, the beam of the irradiated X-ray might not be properly sized to be irradiated onto the fractured surface. Thus, the measurement value of the outermost surface of side of the glass was used as the X-ray intensity of boron at a depth of 0 µm. Note that the measurement conditions included an acceleration voltage of 15 kV, a beam current of 20 nA, a minimal beam diameter, a measurement time of 10 sec./point, and a measurement element of B (BKα: wavelength (Å): 68.486). The results are shown in FIG. 1.

The result of the composition analysis indicated that in Sample No. 25 after the constant high-temperature/constant high-humidity test, the X-ray intensity of boron from the outermost surface to a depth of 1.5 µm was reduced compared to the X-ray intensity of boron before the test. Furthermore, after the heating treatment, the X-ray intensity of boron to a depth of 2.5 µm was reduced compared to the X-ray intensity of boron before the test. On the other hand, in Sample No. 7 after the constant high-temperature/constant high-humidity test, the X-ray intensity of boron in the depth direction did not change compared to the X-ray intensity of boron before the test. Sample No. 26 was not measured, but from the similar glass composition and the behavior with regard to the change in dielectric properties, it is presumed that the same phenomenon as that of Sample No. 25 occurs.

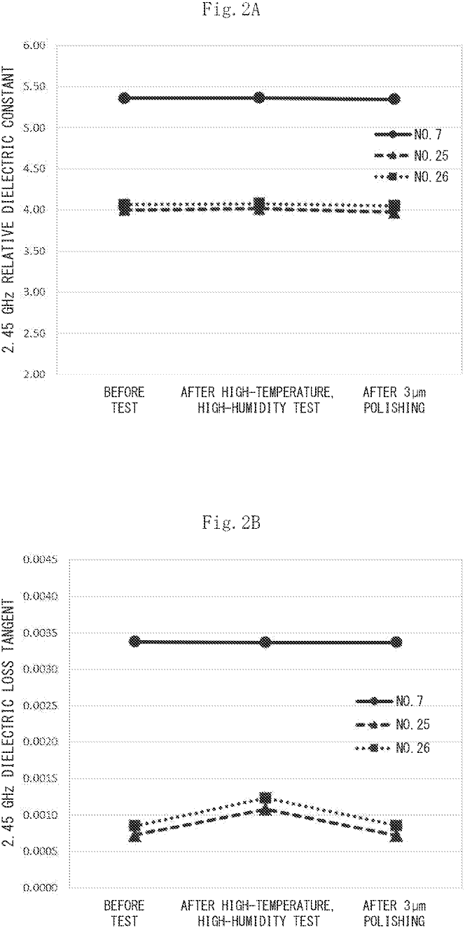

Next, for Sample Nos. 7, 25, and 26, in order to examine the impact on the dielectric loss tangent with respect to the compositional change of the glass surface, the constant high-temperature/constant high-humidity test was conducted for a test time of 48 hours at a temperature of 120° C. and a relative humidity of 85%, after which the glass surface was polished with sandpaper without applying moisture. The results of the compositional analysis indicated that with the sample after the constant high-temperature/constant high-humidity test, the amount of boron decreased at the positions from the surface of the glass to a depth of approximately 1 µm, and therefore a thickness of 3 µm was polished from the glass surface. After polishing, the relative dielectric constant and dielectric loss tangent at 25° C. and a frequency of 2.45 GHz were measured by the cavity resonator method. The results are presented in FIG. 2.

As is clear from FIG. 2, the dielectric loss tangents after polishing of Sample Nos. 25 and 26 were the same as before the constant high-temperature/constant high-humidity test. On the other hand, the dielectric loss tangent of Sample No. 7 was the same value before and after the constant high-temperature/constant high-humidity test and was also the same value after polishing. The relative dielectric constant values of Sample Nos. 7, 25, and 26 were all substantially unchanged before and after polishing.

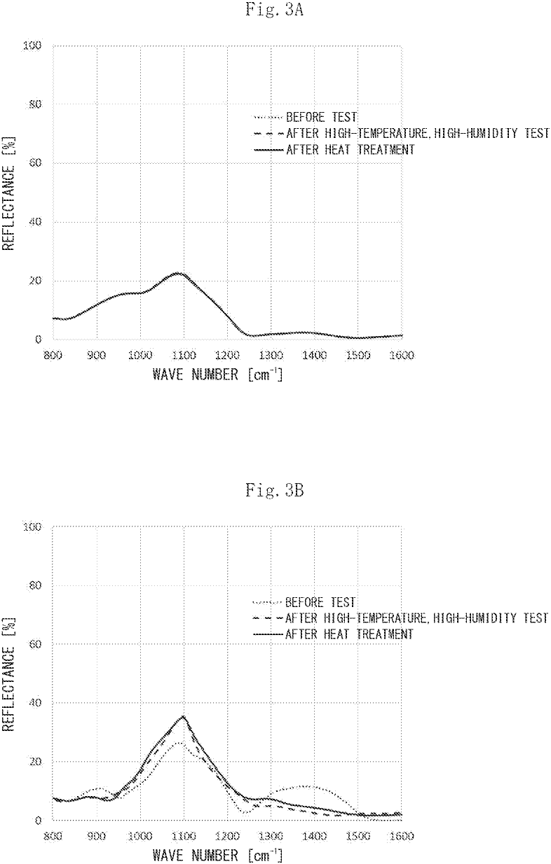

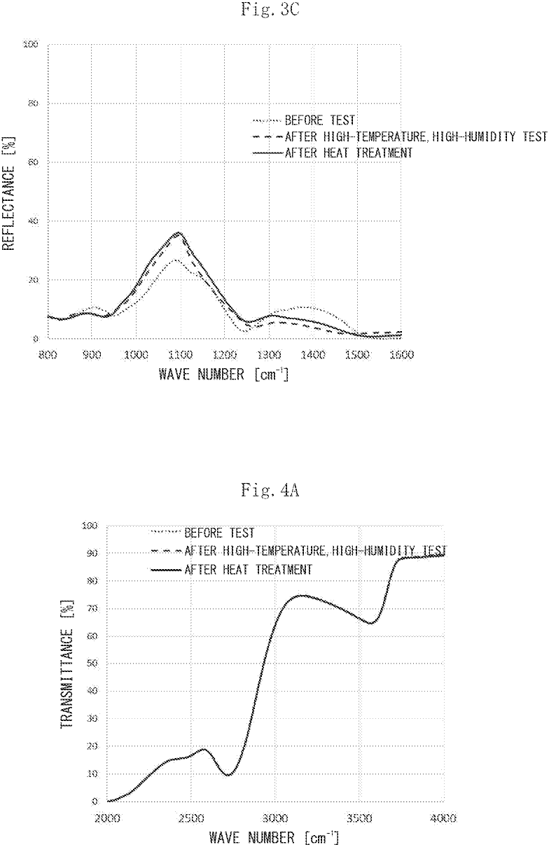

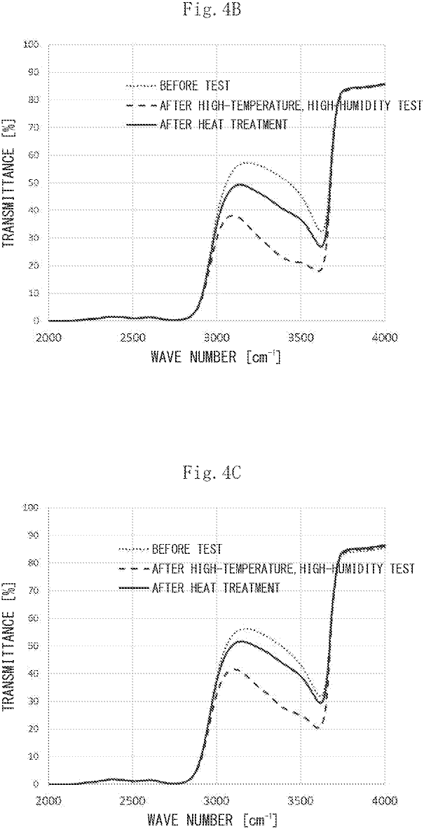

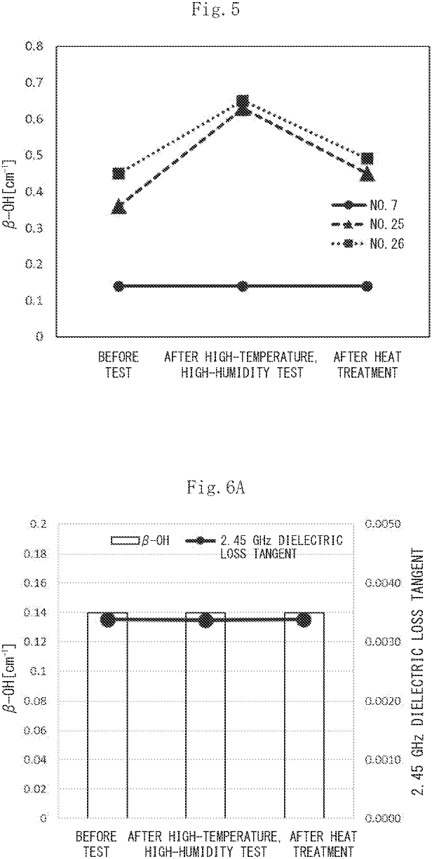

Finally, for Sample Nos. 7, 25, and 26, the reflectance spectrum and the transmittance spectrum in the infrared wavelength range were measured using the Fourier transform infrared spectrophotometer (FT-IR) before and after the constant high-temperature/constant high-humidity test conducted for a test time of 48 hours at a temperature of 120° C. and a relative humidity of 85%. Similarly, the reflectance spectrum and the transmittance spectrum in the infrared wavelength range were measured for a case in which the sample after the constant high-temperature/constant high-humidity test was held for 3 hours at a temperature of the annealing point plus 30° C., and then cooled to room temperature at a rate of -3° C./minute. The β—OH values of each sample were collectively calculated from the transmittance spectrum. The reflectance spectra of Sample No. 7 are shown in FIG. 3(a), the reflectance spectra of Sample No. 25 are shown in FIG. 3(b), and the reflectance spectra of Sample No. 26 are shown in FIG. 3(c). The transmittance spectra of Sample No. 7 are shown in FIG. 4(a), the transmittance spectra of Sample No. 25 are shown in FIG. 4(b), and the transmittance spectra of Sample No. 26 are shown in FIG. 4(c). The changes in β—OH values of Sample No. 7, Sample No. 25, and Sample No. 26 are shown in FIG. 5.

As is clear from FIGS. 3 and 4, Sample Nos. 25 and 26 exhibited changes in the reflectance spectrum and in the transmittance spectrum before and after the constant high-temperature/constant high-humidity test and after the heating treatment. These changes indicate that there had been changes in the bonding state or amount of bonding between silicon atoms (Si) and oxygen atoms (O) in the glass, and between the boron atoms (B) and the oxygen atoms (O) in the glass, and the amount of moisture, and also there had been a change in the structure of the glass. Note that in the reflectance spectra of FIG. 3, the peaks in the vicinity of 900 cm⁻¹ and 1300 to 1500 cm⁻¹ represent the stretching vibrations of BO₃ and BO₄, and the peak in the vicinity of 1100 cm⁻¹ represents stretching vibrations of Si and O bonds. In the transmittance spectra of FIG. 4, the peak near 3600 cm⁻¹ represent a hydroxyl group that is hydrogen bonded with non-crosslinked oxygen in the glass.

The β—OH values of Sample Nos. 7, 25, and 26 were calculated from the transmittance spectra. The β—OH values of Sample Nos. 25 and 26 were higher after the constant high-temperature/constant high-humidity test in comparison to those before the test. When the heating treatment was implemented after the constant high-temperature/constant high-humidity test, the β—OH values decreased compared to those after the constant high-temperature/constant high-humidity test. On the other hand, in Sample No. 7, the β—OH values did not change in any of the measurements.

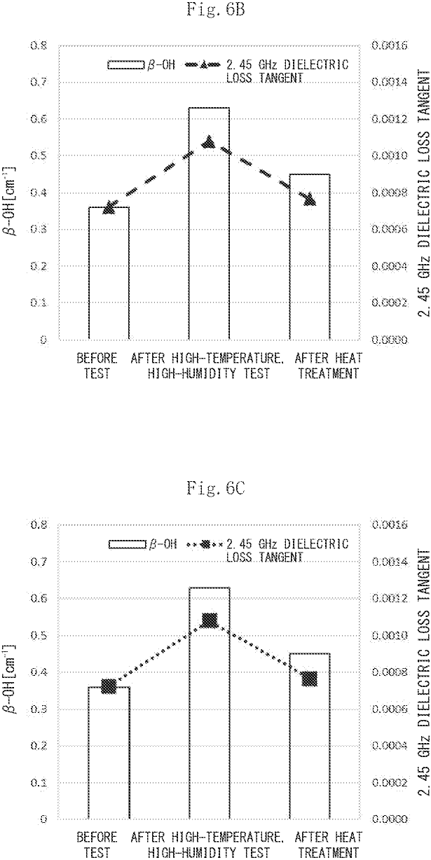

Note that FIG. 6(a) shows the relationship between the β—OH values and the dielectric loss tangent at a temperature of 25° C. and a frequency of 2.45 GHz of Sample No. 7. FIG. 6(b) shows the relationship between the β—OH values and the dielectric loss tangent at a temperature of 25° C. and a frequency of 2.45 GHz of Sample No. 25. FIG. 6(c) shows the relationship between the β-OH values and the dielectric loss tangent at a temperature of 25° C. and a frequency of 2.45 GHz of Sample No. 26.

The presumed mechanism for the change in the dielectric loss tangent is presented below.

From the measurement results for the relative dielectric constant and dielectric loss tangent after polishing the thickness of 3 _{[t}m at the surface according to FIG. 2, the change in the dielectric loss tangent this time is presumed to be brought about by the change in the glass surface.

Sample Nos. 25 and 26 exhibited no precipitation of foreign matter after the constant high-temperature/constant high-humidity test. From the results of the composition analysis of FIG. 1, it is presumed that the boron on the glass surface was sublimated as H₃BO₃ during the constant high-temperature/constant high-humidity test. In addition, it is presumed that H₂O penetrated into the locations from which H₃BO₃ was removed at the glass surface during the constant high-temperature/constant high-humidity test, and some of the H₂O molecules were bonded as hydroxyl groups (—OH), and therefore the β—OH value, which is indicative of the amount of moisture in the glass after the constant high-temperature/constant high-humidity test, increased. In addition, it is surmised that when the heating treatment was implemented after the constant high-temperature/constant high-humidity test, the hydroxyl groups on the glass surface were dissociated as H₂O, resulting in a decrease in hydroxyl groups, and therefore the β—OH value decreased after the heating treatment, and the dielectric loss tangent approached the value before the test (see FIG. 6).

One of the reasons for the change in the dielectric loss tangent due to the change in the β—OH value, or in other words, the change in the moisture content, is thought to be due to the polarization effect of water molecules and of the hydroxyl groups (—OH), which are assumed to be present in the voids of the glass network. Typically, hydroxyl groups tend to polarize from differences in the electronegativity of the constituent elements (O and H), and when an electromagnetic field is applied externally, the polarized hydroxyl groups try to orient themselves along the electromagnetic field. The dielectric loss tangent indicates a delay in the orientation of polarized molecules when an electromagnetic field is applied, and the dielectric loss tangent varies depending on the amount of hydroxyl groups. In the case of the same glass composition, it is thought that the dielectric loss tangent increases as the amount of hydroxyl groups increases (see FIG. 6).

From the results of this examination, it is presumed that a change in the dielectric loss tangent did not occur in Sample No. 7 because, in comparison to Sample Nos. 25 and 26, Sample No. 7 had, for example, less boron in the composition and the reactivity with moisture was low (see FIG. 6). Thus, this phenomenon demonstrates that a change in the dielectric loss tangent can be effectively suppressed by configuring the glass composition to a suitable range, in particular, by configuring the product of the content (mol%) of B₂O₃ — Al₂O₃ and the content (mol%) of B₂O₃ —(MgO + CaO + SrO + BaO) to 600 or less, and particularly to 260 or less.

### INDUSTRIAL APPLICABILITY

The glass of the present invention is suitable for use as a standard sample for measuring dielectric properties in a high frequency range, and is also suitable as a substrate requiring low dielectric properties including a substrate for a printed wiring board, a substrate for a glass antenna, a substrate for a micro LED, a substrate for glass interposer, or a substrate for back grinding of different materials such as metal and ceramic.

1. A glass having a rate of change of 30% or less in a dielectric loss tangent at a measurement temperature of 25° C. and a measurement frequency of 2.45 GHz after being subjected to a constant temperature/constant humidity test for 1000 hours at a temperature of 85° C. and a relative humidity of 85%.

2. The glass according to claim 1, wherein the glass has the rate of change of 30% or less in the dielectric loss tangent at a measurement temperature of 25° C. and a measurement frequency of 2.45 GHz after being subjected to a constant high-temperature/constant high-humidity test (JIS-C0096-2001) for 12 hours at a temperature of 120° C. and a relative humidity of 85%.

3. The glass according to claim 1, wherein, when the X-ray intensity of boron is analyzed in a depth direction from an outermost surface of the glass, after the glass has been subjected to the constant high-temperature/constant high-humidity test (JIS-C0096-2001) for 48 hours at a temperature of 120° C. and a relative humidity of 85%, a depth at which an X-ray intensity of boron is reduced by 50% compared to an X-ray intensity of boron at a depth of 15 µm is 5 µm or less.

4. The glass according to claim 1, wherein, in a composition of the glass, a product of a content (mol%) of B₂O₃ — Al₂O₃ and a content (mol%) of B₂O₃ — (MgO + CaO + SrO + BaO) is 260 or less.

5. The glass according to claim 1, wherein the glass is crystallized glass.

6. The glass according to claim 1, wherein as a composition, the glass comprises from 60 to 75 mol% of SiO₂, from 0 to 15 mol% of Al₂O₃, from 8 to 28 mol% of B₂O₃, from 0 to 3 mol% of Li₂O + Na₂O + K₂O, and from 0 to 14 mol% of MgO + CaO + SrO + BaO, and the glass has a relative dielectric constant of 6 or less at 25° C. and a frequency of 2.45 GHz.

7. The glass according to claim 1, wherein as a composition, the glass comprises from 75 to 85 mol% of SiO₂, from 0 to 5 mol% of Al₂O₃, from 10 to 20 mol% of B₂O₃, from 0 to 5 mol% of Li₂O, from 1 to 10 mol% of Na₂O, from 0 to 5 mol% of K₂O, and from 3 to 10 mol% of Li₂O + Na₂O + K₂O, and the glass has the relative dielectric constant of 6 or less at 25° C. and a frequency of 2.45 GHz.

8. The glass according to claim 5, wherein the glass is a crystallized glass, and as a composition, the glass comprises from 55 to 75 mol% of SiO₂, from 10 to 20 mol% of Al₂O₃, 2 mol% or greater of Li₂O, from 0.5 to 3 mol% of TiO₂, from 2 to 5 mol% of TiO₂ + ZrO₂, and from 0.1 to 0.5 mol% of SnO₂, and the glass has the relative dielectric constant of 7 or less at 25° C. and a frequency of 2.45 GHz.

9. The glass according to claim 1, wherein the glass is used as a measurement standard material in a measurement of dielectric properties.

10. A method for measuring dielectric properties using a measurement standard material, the method including using the glass described in claim 1 as the measurement standard material.

11. The method for measuring dielectric properties according to claim 10, wherein the method includes subjecting the measurement standard material to heat treatment at a temperature equal to or higher than an annealing point of the glass before measuring the dielectric properties.
